(19) United States
(12) Patent Application Publication
(10) Pub. No.: US 2025/0031374 A1
(43) Pub. Date: Jan. 23, 2025

(54) MICROELECTRONIC DEVICES INCLUDING PSEUDO GATE-ALL-AROUND MEMORY CELL STRUCTURES, AND RELATED MEMORY DEVICES AND ELECTRONIC SYSTEMS

(71) Applicant: Micron Technology, Inc., Boise, ID (US)

(72) Inventor: Yoshiaki Fukuzumi, Tokyo (JP)

(21) Appl. No.: 18/745,903

(22) Filed: Jun. 17, 2024

Related U.S. Application Data
(60) Provisional application No. 63/514,773, filed on Jul. 20, 2023.

(51) Int. Cl. H10B 43/27

(52) U.S. Cl. CPC H10B 43/27

(57) ABSTRACT

A method of forming a microelectronic device includes forming a preliminary stack structure over a base structure, forming a first slot vertically extending through the preliminary stack structure, forming a dielectric mask material over exposed surfaces of sidewalls of the preliminary stack structure partially defining the first slot, forming gaps in the dielectric mask material, forming voids in sacrificial material and insulative material of the preliminary stack structure via the gaps in the dielectric mask material, forming memory cell material within the voids, and removing a portion of the memory cell material to form vertical memory string structures vertically extending through the preliminary stack structure. Related microelectronic devices, electronic devices, and related methods are also disclosed.

### CROSS-REFERENCE TO RELATED APPLICATION

This application claims the benefit under 35 U.S.C. § 119 (c) of U.S. Provisional Patent Application Ser. No. 63/514,773, filed Jul. 20, 2023, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices including pseudo gate-all-around memory cells, and to related microelectronic devices, memory devices, and electronic systems.

### BACKGROUND

Microelectronic device designers often desire to increase the level of integration or density of features within a microelectronic device by reducing the dimensions of the individual features and by reducing the separation distance between neighboring features. In addition, microelectronic device designers often seek to design architectures that are not only compact, but offer performance advantages, as well as simplified designs.

One example of a microelectronic device is a memory device. Memory devices are generally provided as internal integrated circuits in computers or other electronic devices. There are many types of memory devices including, but not limited to, non-volatile memory devices (e.g., NAND Flash memory devices). One way of increasing memory density in non-volatile memory devices is to utilize vertical memory array (also referred to as a “three-dimensional (3D) memory array”) architectures. A conventional vertical memory array includes strings of memory cells vertically extending through one or more stack structures including tiers of conductive material and insulative material. Each string of memory cells may include at least one select device coupled thereto. Such a configuration permits a greater number of switching devices (e.g., transistors) to be located in a unit of die area (i.e., length and width of active surface consumed) by building the array upwards (e.g., vertically) on a die, as compared to structures with conventional planar (e.g., two-dimensional) arrangements of transistors.

Vertical memory array architectures generally include electrical connections between the conductive material of a tier of the stack structure(s) of the memory device and control logic devices (e.g., string drivers) so that the memory cells of the vertical memory array can be uniquely selected for writing, reading, or erasing operations.

Unfortunately, as feature packing densities have increased and margins for formation errors have decreased, conventional fabrication methods and resulting structural configurations have resulted in undesirable defects that can diminish desired memory device performance, reliability, and durability.

### BRIEF DESCRIPTION OF THE DRAWINGS

FIG. 1 is a simplified, partial top-down view of a microelectronic device structure at a processing stage of a method of forming a microelectronic device, in accordance with embodiments of the disclosure.

FIGS. 2A through 2N are simplified, perspective, partial cutaway views of a portion of the microelectronic device structure shown in FIG. 1 at different processing stages of the method of forming the microelectronic device.

FIG. 3 is a schematic block diagram illustrating an electronic system, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. The description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only, and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, a “memory device” means and includes microelectronic devices exhibiting memory functionality, but not necessarily limited to memory functionality. Stated another way, and by way of non-limiting example only, the term “memory device” includes not only conventional memory (e.g., conventional volatile memory, such as conventional dynamic random access memory (DRAM); conventional non-volatile memory, such as conventional NAND memory), but also includes an application-specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one of the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, spatially relative terms, such as “beneath,” “below,” “lower,” “bottom,” “over,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of”' other elements or features would then be oriented “above” or “on top of” the other elements or features. Moreover, if a material is formed to cover a surface (e.g., a substantially vertical sidewall of a structure), the material may be referred to as being formed “over” the surface even though the material may not be spatially above the covered surface. Likewise, the surface may be referred to as being “under” the formed material. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the terms “hole” and “slot” mean and include a volume extending through at least one structure or at least one material, leaving a void (e.g., gap) in that at least one structure or at least one material, or a volume extending between structures or materials, leaving a gap between the structures or materials. Unless otherwise described, a “hole” and/or “slot” is not necessarily empty of material. That is, a “hole” and/or “slot” is not necessarily void space. A “hole” and/or “slot” formed in or between structures or materials may comprise structure(s) or material(s) other than that in or between which the hole or slot is formed. And, structure(s) or material(s) “exposed” within a “hole” and/or “slot” is (are) not necessarily in contact with an atmosphere or nonsolid environment. Structure(s) or material(s) “exposed” within a “hole” and/or “slot” may be adjacent or in contact with other structure(s) or material(s) that is (are) disposed within the “hole” and/or “slot.”

As used herein, the singular forms “a,” “an,” and “the” are intended to include the plural forms as well, unless the context clearly indicates otherwise.

As used herein, “and/or” includes any and all combinations of one or more of the associated listed items.

As used herein, the phrase “coupled to” refers to structures operatively connected with each other, such as electrically connected through a direct Ohmic connection or through an indirect connection (e.g., by way of another structure).

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formulae are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, “sacrificial material” means and includes one material that may be selectively removed relative to one or more other materials (e.g., one or more insulative materials). The sacrificial material may be selectively etchable relative to the one or more other materials during common (e.g., collective, mutual) exposure to a first etchant; and the one or more other materials may be selectively etchable to the sacrificial material during common exposure to a second, different etchant. As used herein, a material is “selectively etchable” relative to another material if the material exhibits an etch rate that is at least about five times (5×) greater than the etch rate of another material, such as about ten times (10×) greater, about twenty times (20×) greater, or about forty times (40×) greater. By way of non-limiting example, depending on the material composition of the one or more other materials, the sacrificial material may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbOₓ, TiOₓ, ZrOₓ, TaOₓ, and a MgOₓ), at least one dielectric nitride material (e.g., SiN_{y}), at least one dielectric oxynitride material (e.g., SiOₓN_{y}), at least one dielectric oxycarbide material (e.g., SiOₓC_{y}), at least one hydrogenated dielectric oxycarbide material (e.g., SiCₓO_{y}H_{z}), at least one dielectric carboxynitride material (e.g., SiOₓC_{z}N_{y}), and at least one semiconductive material (e.g., polycrystalline silicon). The sacrificial material may, for example, be selectively etchable relative to the one or more other materials during common exposure to a wet etchant comprising phosphoric acid (H₃PO₄). In addition, a “sacrificial structure” means and includes a structure formed of and including sacrificial material.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively-doped polysilicon, conductively-doped germanium (Ge), conductively-doped silicon germanium (SiGe)). In addition, a “conductive structure” means and includes a structure formed of and including conductive material.

As used herein, the term “semiconductor material” refers to a material having an electrical conductivity between those of insulative materials and conductive materials. For example, a semiconductor material may have an electrical conductivity of between about 10⁻⁸ Siemens per centimeter (S/cm) and about 10⁴ S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., AlₓGa₁₋ₓAs), and quaternary compound semiconductor materials (e.g., GaₓIn₁₋ₓAs_{y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn_{z}O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn_{z}O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn_{z}O), gallium zinc tin oxide (GaₓZn_{y}Sn_{z}O), zirconium zinc tin oxide (ZrₓZn_{y}Sn_{z}O), and other similar materials.

As used herein, the term “homogeneous” means relative amounts of elements included in a feature (e.g., a material, a structure) do not vary throughout different portions (e.g., different horizontal portions, different vertical portions) of the feature. Conversely, as used herein, the term “heterogeneous” means relative amounts of elements included in a feature (e.g., a material, a structure) vary throughout different portions of the feature. If a feature is heterogeneous, amounts of one or more elements included in the feature may vary stepwise (e.g., change abruptly), or may vary continuously (e.g., change progressively, such as linearly, parabolically) throughout different portions of the feature. The feature may, for example, be formed of and include a stack of at least two different materials.

As used herein, the term “pitch” refers to a distance between identical points in two adjacent (e.g., neighboring) features of a repeating pattern.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching), ion milling, abrasive planarization (e.g., chemical-mechanical planarization (CMP)), or other known methods.

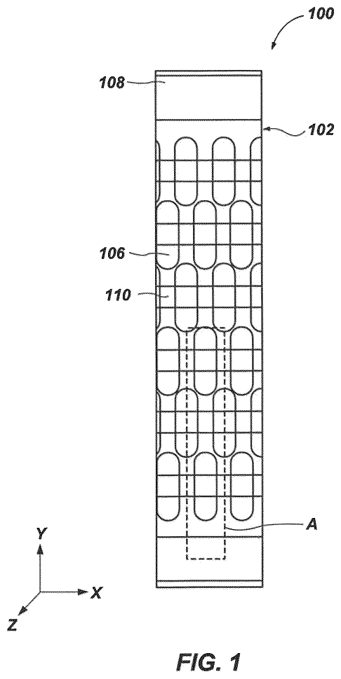

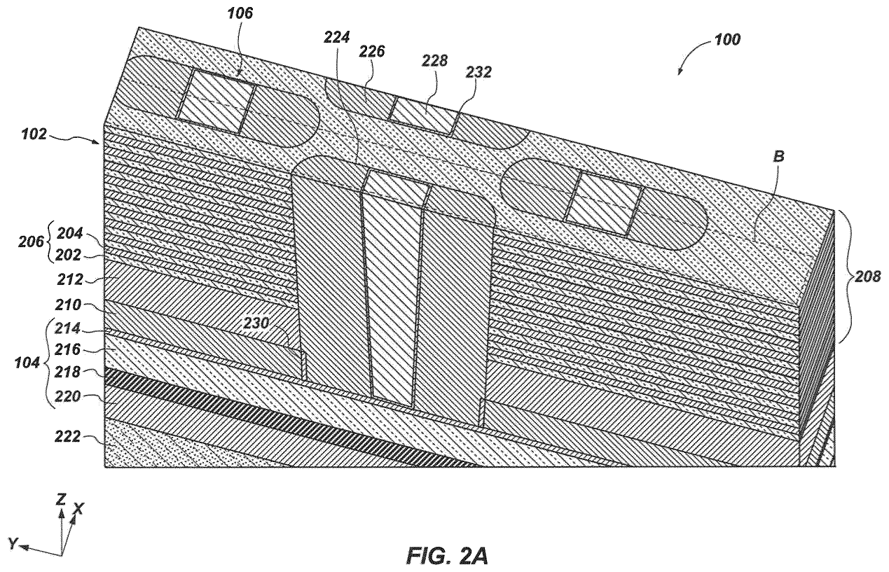

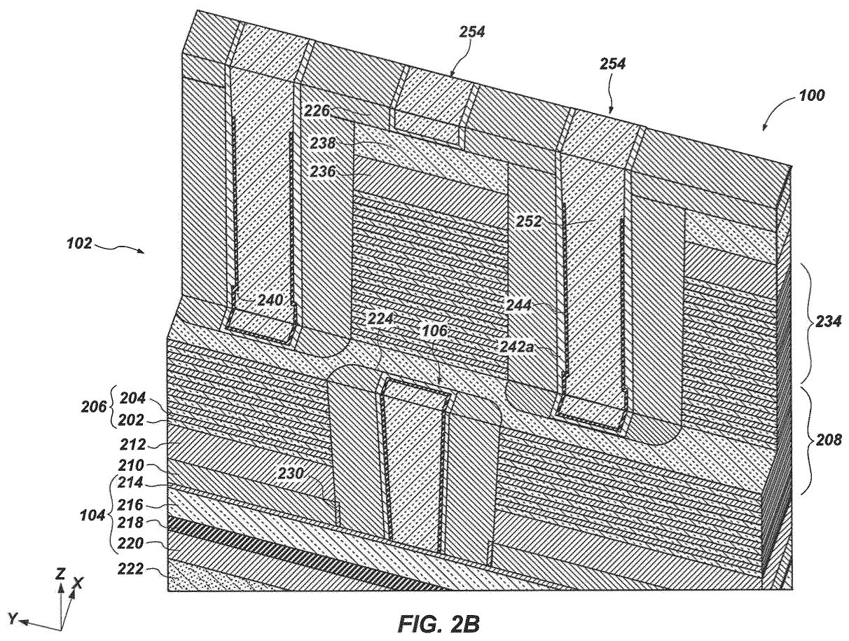

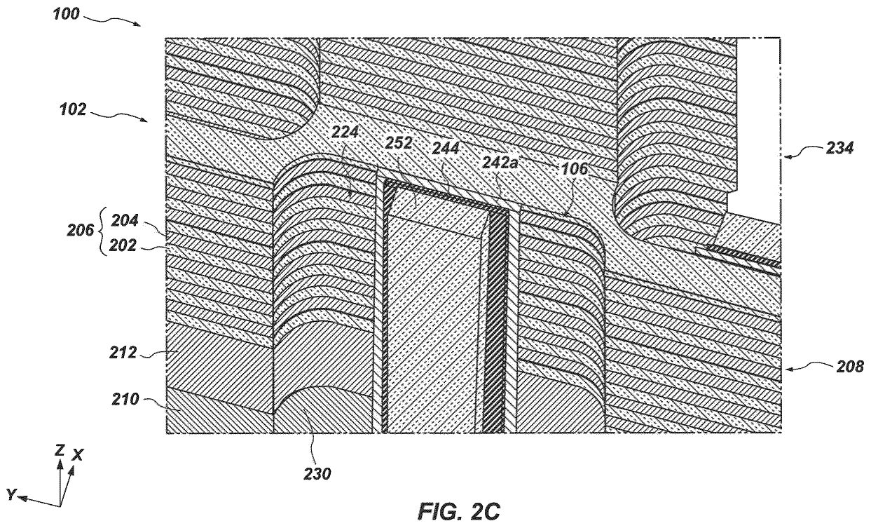

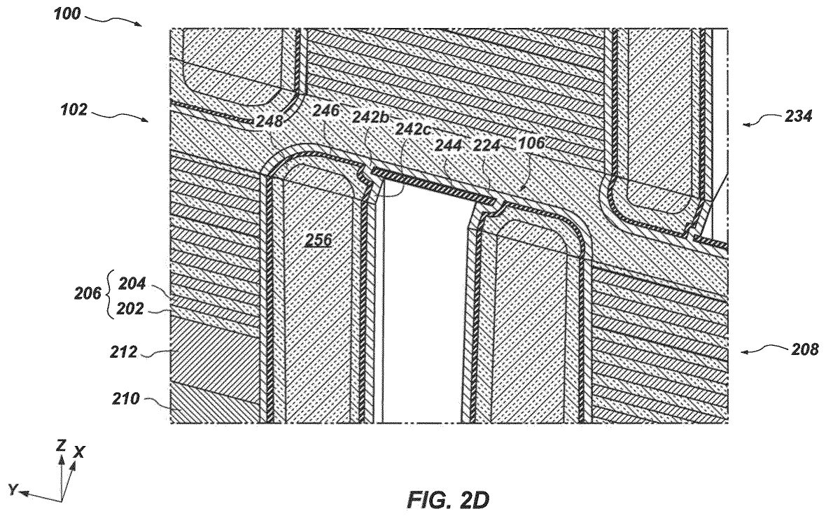

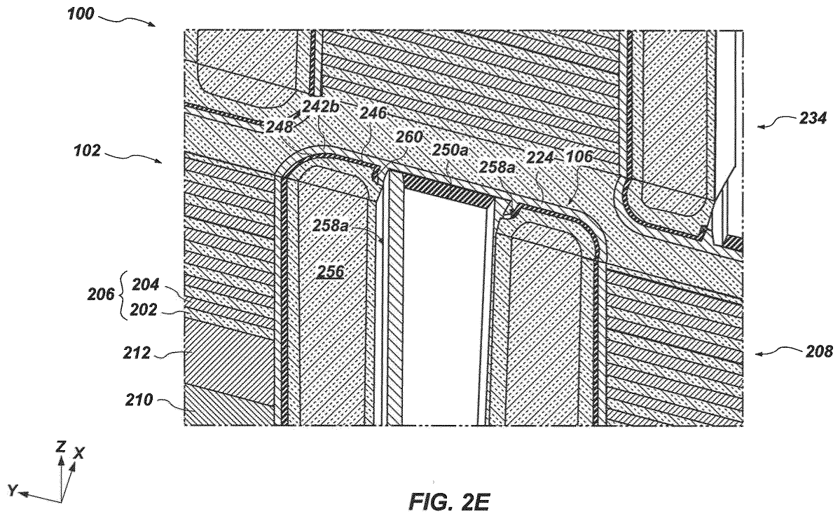

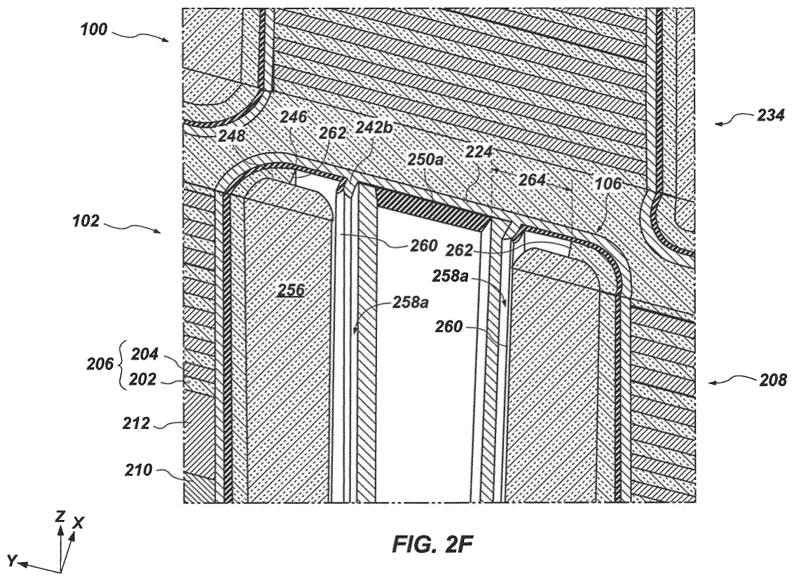

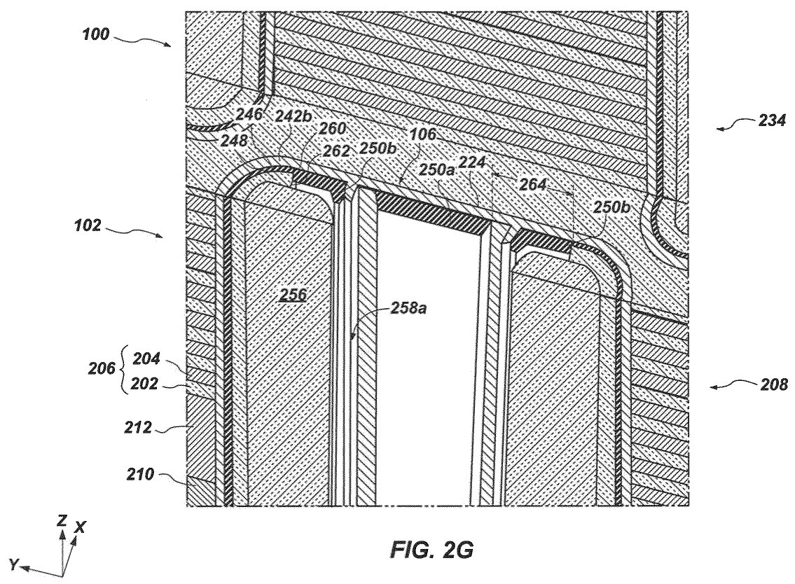

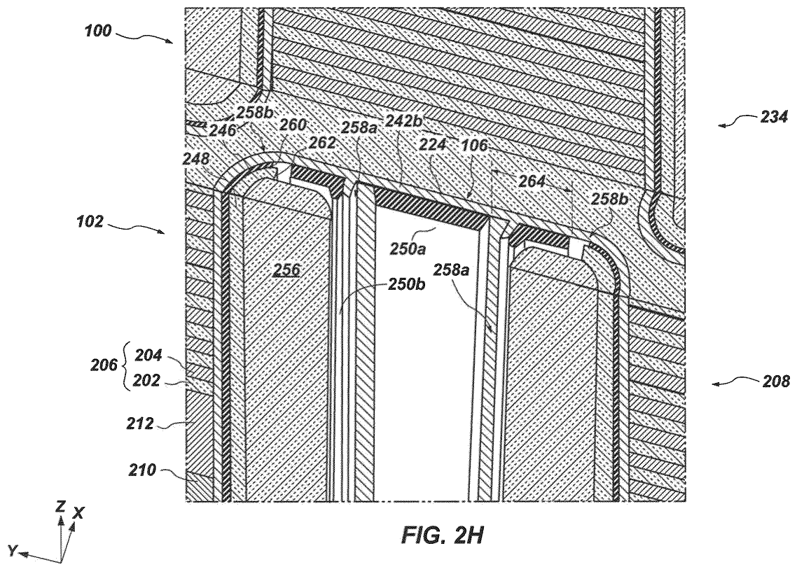

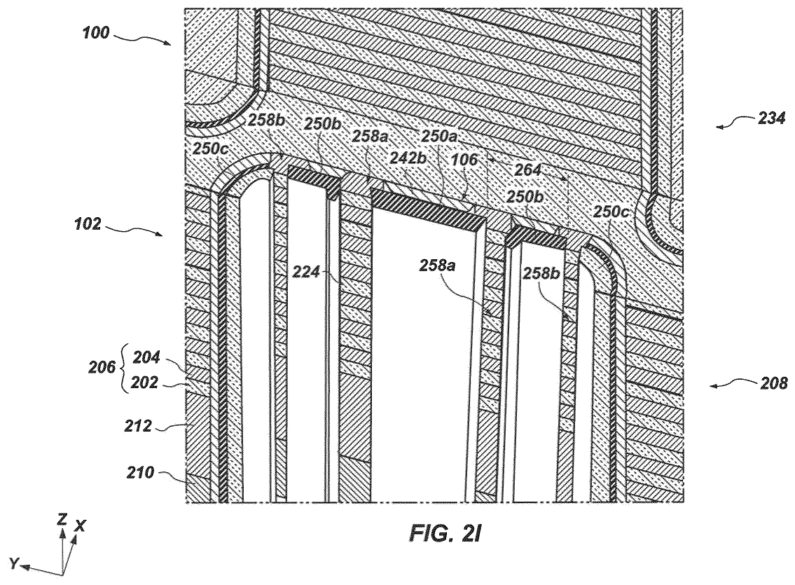

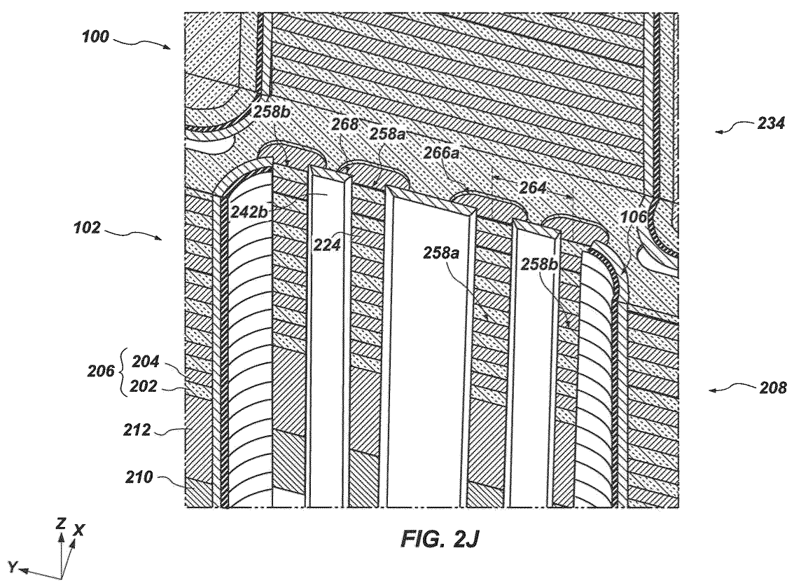

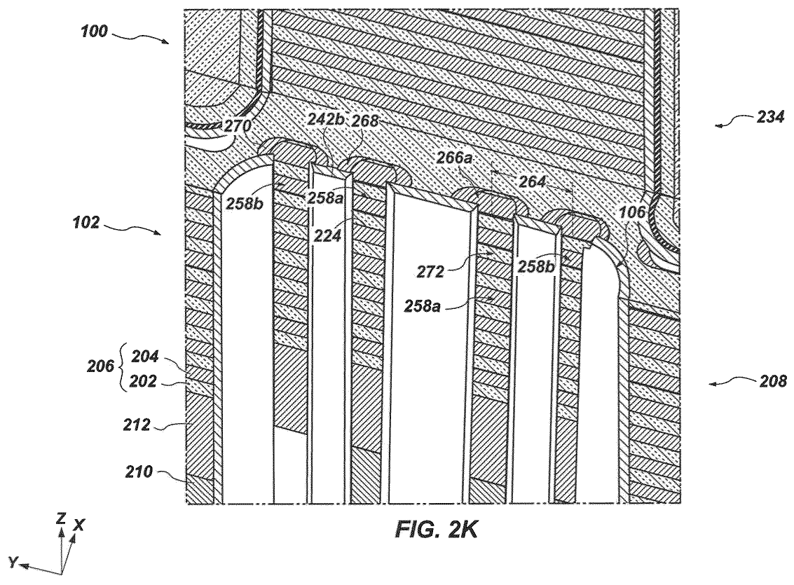

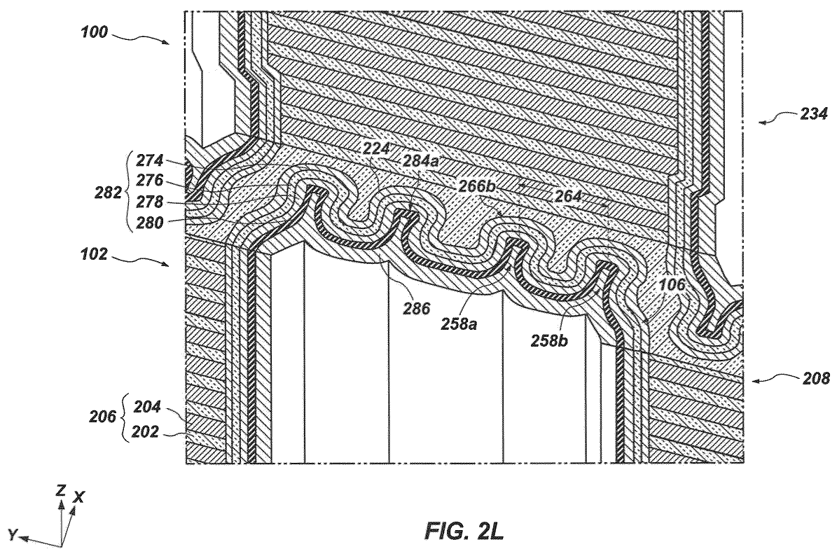

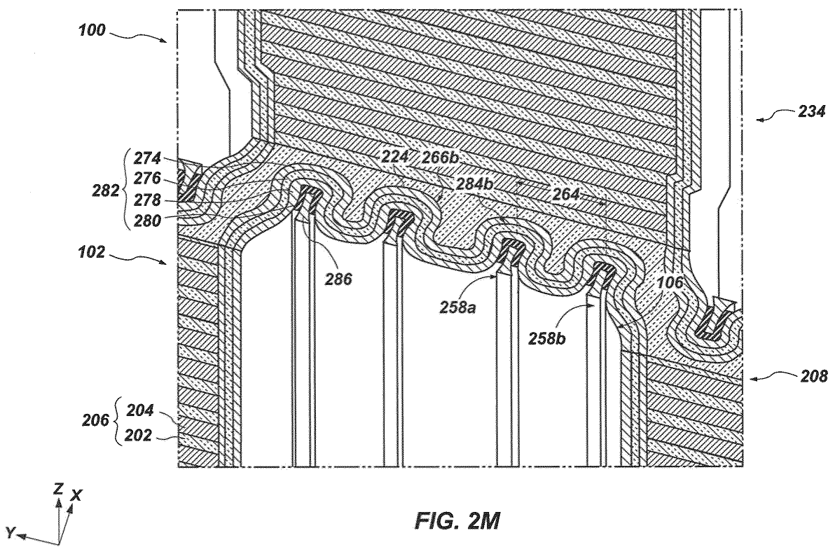

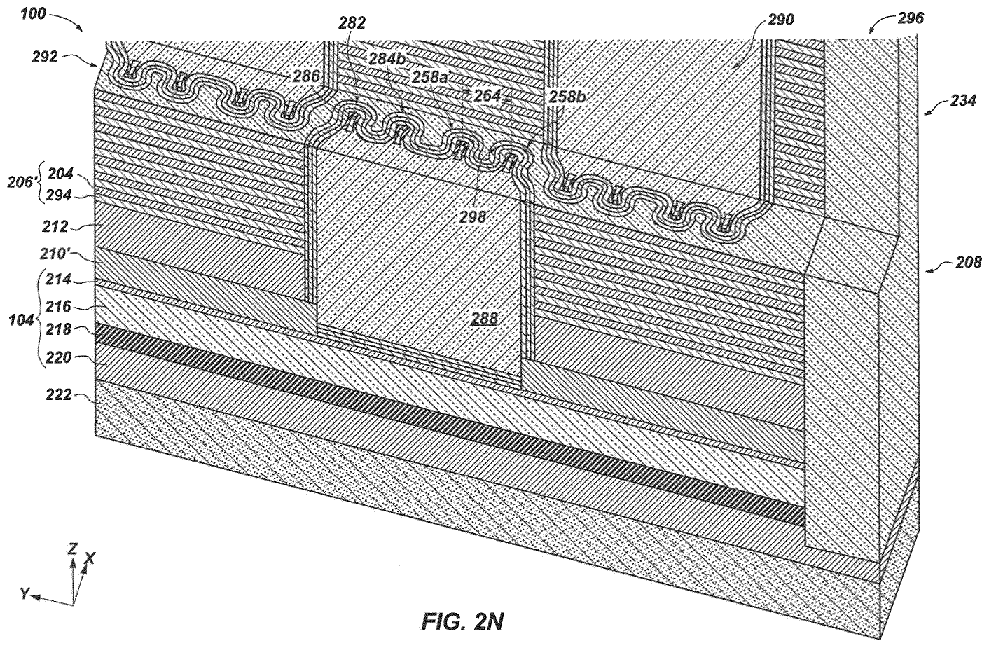

FIG. 1 and FIGS. 2A through 2N are various views (described in further detail below) illustrating a microelectronic device structure 100 at different processing stages of a method of forming a microelectronic device (e.g., a memory device, such as a 3D NAND Flash memory device), in accordance with embodiments of the disclosure. With the description provided below, it will be readily apparent to one of ordinary skill in the art that the structures (e.g., the microelectronic device structure 100) and devices (e.g., microelectronic devices) described herein may be employed in various relatively larger devices and/or systems. For clarity and case of understanding the drawings and associated description, not all features (e.g., regions, structures, materials, devices) of the microelectronic device structure 100 depicted in one or more of FIG. 1 and FIGS. 2A through 2N are depicted in the one or more other of FIG. 1 and FIGS. 2A through 2N.

FIG. 1 depicts a simplified, partial top-down view of a microelectronic device structure 100 at a processing stage of a method of forming a microelectronic device, in accordance with embodiments of this disclosure. The microelectronic device structure 100 may be formed to include a preliminary stack structure 102 over a base structure 104 (FIG. 2A). The preliminary stack structure 102 may include one or more first slots 106 (e.g., memory cell slots), second slot regions 108 (e.g., replacement gate slot regions), and third slot regions 110 therein. The first slots 106 may define voids vertically extending through the preliminary stack structure 102. The second slot regions 108 and the third slot regions 110 may define regions where voids may be formed at later processing stages.

As shown in FIG. 1, the first slots 106 may include multiple, substantially linear voids in the preliminary stack structure 102. An individual first slot 106 may include a relatively long edge (e.g., horizontal boundary) horizontally extending in a first horizontal direction (e.g., the Y-direction) and a relatively short edge horizontally extending in a second horizontal direction (e.g., the X-direction) substantially orthogonal to the first horizontal direction. The first slots 106 may individually exhibit a single, oblong horizontal cross-sectional shape (e.g., an obround horizontal cross-sectional shape). Multiple first slots 106 horizontally aligned with one another in the Y-direction and horizontally offset from one another in the X-direction may form rows of first slots 106. Neighboring individual rows of first slots 106 may be horizontally partially offset from one another in the X-direction. Further, neighboring individual rows of first slots 106 may partially horizontally overlap one another in the X- and Y-directions. The first slots 106 may individually have a horizontal width in the X-direction within a range of from about 50 nm to about 200 nm, such as from about 75 nm to about 150 nm, from about 90 nm to about 125 nm, or about 100 nm. The first slots 106 may individually have a horizontal length in the Y-direction within a range of from about 100 nm to about 400 nm, such as from about 200 nm to about 375 nm, from about 250 nm to about 350 nm, or about 320 nm. The first slots 106 may have a horizontal pitch in the X-direction within a range of from about 100 nm to about 300 nm, such as from about 150 nm to about 250 nm, from about 170 nm to about 200 nm, or about 180 nm. The first slots 106 may have a horizontal pitch in the Y-direction (e.g., the distance in the Y-direction between respective horizontal centers, defined in the Y-direction, of adjacent rows of the first slots 106) within a range of from about 100 nm to about 400 nm, such as from about 200 nm to about 375 nm, from about 250 nm to about 350 nm, or about 300 nm.

The second slot regions 108 may individually have an elongate horizontal cross-sectional shape (e.g., a substantially rectangular horizontal cross-sectional shape). Individual second slot regions 108 may comprise a relatively long boundary horizontally extending in the X-direction, and a relatively short boundary horizontally extending in the Y-direction. Neighboring second slot regions 108 may be individually horizontally spaced from one another in the Y-direction, with multiple first slots 106 disposed therebetween. The second slot regions 108 may individually have a horizontal width in the Y-direction within a range of from about 100 nm to about 300 nm, such as from about 150 nm to about 250 nm, from about 175 nm to about 225 nm, or about 200 nm. The second slot regions 108 may have a horizontal pitch in the Y-direction within a range of from about 1000 nm to about 4000 nm, such as from about 1500 nm to about 3000 nm, from about 2000 nm to about 2500 nm, or about 2200 nm.

The third slot regions 110 may substantially continuously extend, in the X-direction, across and between the horizontal profiles of the first slots 106. The third slot regions 110 may have a substantially rectangular horizontal cross-sectional shape. The third slot regions 110 may individually have a horizontal width in the Y-direction within a range of from about 50 nm to about 150 nm, such as from about 75 nm to about 125 nm, from about 90 nm to about 110 nm, or about 100 nm. The third slot regions 110 may individually have a horizontal pitch in the Y-direction substantially equivalent to the corresponding pitch of the individual first slots 106 in the Y-direction.

FIGS. 2A through 2N depict simplified, perspective, partial cutaway views of the microelectronic device structure 100 at different processing stages of a method of forming a microelectronic device. For clarity and case of understanding the drawings and associated description, a section of the microelectronic device structure 100, indicated by region A in FIG. 1, is depicted in FIGS. 2A through 2N. FIGS. 2B through 2N show the section of the microelectronic device structure 100 of the region A of the microelectronic device structure 100 depicted in FIG. 2A, further sectioned at region B (FIG. 2A), at different processing stages of the method of forming a microelectronic device following the processing stage described hereinbelow with reference to FIG. 2A.

FIG. 2A is a simplified, partial perspective cross-sectional view of the microelectronic device structure 100 at a processing stage of forming the microelectronic device structure 100. As shown in FIG. 2A, the microelectronic device structure 100 may be formed to include the preliminary stack structure 102 including a vertically alternating (e.g., in a Z-direction) sequence of sacrificial material 202 and insulative material 204 arranged in tiers 206. The tiers 206 of the preliminary stack structure 102 may individually include the sacrificial material 202 vertically neighboring (e.g., directly vertically adjacent in the Z-direction) the insulative material 204.

The insulative material 204 of the individual tiers 206 of the preliminary stack structure 102 may be formed of and include at least one dielectric material, such one or more of at least one dielectric oxide material (e.g., one or more of SiOₓ, phosphosilicate glass, borosilicate glass, borophosphosilicate glass, fluorosilicate glass, AlOₓ, HfOₓ, NbO₋ₓ₋, TiOₓ, ZrOₓ, TaOₓ, and MgOₓ), at least one dielectric nitride material (e.g., SiN_{y}), at least one dielectric oxynitride material (e.g., SiOₓN_{y}), and at least one dielectric carboxynitride material (e.g., SiOₓC_{z}N_{y}). In some embodiments, the insulative material 204 of each of the tiers 206 of the preliminary stack structure 102 is formed of and includes a dielectric oxide material, such as SiOₓ (e.g., SiO₂). The insulative material 204 of each of the tiers 206 may be substantially homogeneous, or the insulative material 204 of one or more (e.g., each) of the tiers 206 may be heterogeneous.

The sacrificial material 202 of each of the tiers 206 of the preliminary stack structure 102 may be formed of and include at least one material (e.g., at least one insulative material) that may be selectively removed relative to the insulative material 204. The sacrificial material 202 may be selectively etchable relative to the insulative material 204 during common (e.g., collective, mutual) exposure to a first etchant; and the insulative material 204 may be selectively etchable to the sacrificial material 202 during common exposure to a second, different etchant. By way of non-limiting example, depending on the material composition of the insulative material 204, the sacrificial material 202 may be formed of and include one or more of at least one dielectric oxide material (e.g., one or more of SiOₓ, phosphosilicate glass, borosilicate glass, borophosphosilicate glass, fluorosilicate glass, AlOₓ, HfOₓ, NbO₋ₓ₋, TiOₓ, ZrOₓ, TaOₓ, and a MgOₓ), at least one dielectric nitride material (e.g., SiN_{y}), at least one dielectric oxynitride material (e.g., SiOₓN_{y}), at least one dielectric oxycarbide material (e.g., SiOₓC_{y}), at least one hydrogenated dielectric oxycarbide material (e.g., SiCₓO_{y}H_{z}), at least one dielectric carboxynitride material (e.g., SiOₓC_{z}N_{y}), and at least one semiconductive material (e.g., polycrystalline silicon). In some embodiments, the sacrificial material 202 of each of the tiers 206 of the preliminary stack structure 102 is formed of and includes a dielectric nitride material, such as SiN_{y} (e.g., Si₃N₄). The sacrificial material 202 may, for example, be selectively etchable relative to the insulative material 204 during common exposure to a wet etchant comprising phosphoric acid (H₃PO₄). The preliminary stack structure 102 may include one or more decks, each deck comprising multiple tiers 206. FIG. 2A depicts the preliminary stack structure 102 with a lower deck 208.

As depicted in FIG. 2A, the microelectronic device structure 100 includes a bottom polysilicon material 210 and a bottom dielectric material 212 under the preliminary stack structure 102. The bottom dielectric material 212 may be vertically positioned (e.g., in the Z-direction) below the tiers 206 and above the bottom polysilicon material 210. The bottom polysilicon material 210 may be vertically positioned below the bottom dielectric material 212 and above the base structure 104. The bottom dielectric material 212 may be formed of and include insulative material. The bottom dielectric material 212 may be vertically thicker (e.g., in the Z-direction) than insulative material 204 and/or the sacrificial material 202 of individual tiers 206 of the preliminary stack structure 102. The bottom polysilicon material 210 may be formed of and include a doped polysilicon material including P-type dopant (e.g., polysilicon doped with one or more of boron, aluminum, and gallium). The bottom polysilicon material 210 may be vertically thicker (e.g., in the Z-direction) than the insulative material 204 and/or the sacrificial material 202 of individual tiers 206 of the preliminary stack structure 102.

The base structure 104 may include multiple materials. For example, the base structure 104 may include a base structure liner material 214, an upper base structure material 216, a middle base structure material 218, and a lower base structure material 220. The base structure liner material 214 may be formed of and include a dielectric oxide material (e.g., silicon oxide). The upper base structure material 216 may be formed of and include semiconductor material, such as relatively lightly doped semiconductor material (e.g., N-doped polysilicon). The middle base structure material 218 be formed of and include semiconductor material, such as relatively heavily doped semiconductor material (e.g., N+doped polysilicon). The lower base structure material 220 may be formed of and include dielectric material.

As shown in FIG. 2A, the microelectronic device structure 100 may further include a substrate 222 vertically underlying the base structure 104. The substrate 222 may comprise a structure or material upon which the base structure 104 is formed. In some embodiments, the substrate 222 comprises a semiconductor wafer (e.g., a silicon wafer). The substrate 222 may have additional features (e.g., regions, materials, structures, devices) at least partially formed therein. For example, the substrate 222, alone or in combination with the base structure 104, may include at least one control logic region including control logic devices configured to control various operations of other features (e.g., the vertical memory string structures 284b depicted in FIG. 2M) of the microelectronic device structure 100. As a non-limiting example, the control logic region includes one or more (e.g., each) of charge pumps (e.g., V_{CCP} charge pumps, V_{NEGWL}, charge pumps, DVC2 charge pumps), delay-locked loop (DLL) circuitry (e.g., ring oscillators), V_{dd} regulators, drivers (e.g., string drivers), page buffers, decoders (e.g., local deck decoders, column decoders, row decoders), sense amplifiers (e.g., equalization (EQ) amplifiers, isolation (ISO) amplifiers, NMOS sense amplifiers (NSAs), PMOS sense amplifiers (PSAs)), repair circuitry (e.g., column repair circuitry, row repair circuitry), I/O devices (e.g., local I/O devices), memory test devices, MUX, error checking and correction (ECC) devices, self-refresh/wear leveling devices, and other chip/deck control circuitry. In some embodiments, the control logic region includes CMOS (complementary metal-oxide-semiconductor) circuitry. In such embodiments, the control logic region may be characterized as having a “CMOS under Array” (“CuA”) configuration.

The first slots 106 may individually be defined as a negative space (e.g., trench, opening, slit) vertically extending within vertical boundaries of and at least partially defined by the preliminary stack structure 102, the bottom dielectric material 212, and the bottom polysilicon material 210. The first slots 106 may extend vertically (e.g., in the Z-direction) through the tiers 206 of the preliminary stack structure 102, the bottom dielectric material 212, and the bottom polysilicon material 210. As shown in FIG. 2A, the first slots 106 may comprise a lower (e.g., in the Z-direction) boundary at least partially defined by a top surface (e.g., an upper surface) of the base structure liner material 214. The preliminary stack structure 102, the bottom dielectric material 212, and the bottom polysilicon material 210 may, in combination, include sidewalls 224 that define horizontal boundaries (e.g., in the X-direction, the Y-direction, and in horizontal directions that are a combination of the X- and Y-directions) of the first slots 106. Individual first slots 106 may be horizontally bounded by two opposing sidewalls 224 that face each other in the X-direction. A pair of opposing sidewalls 224 may form two (2) relatively long horizontal boundaries along the Y-direction of an individual first slot 106.

The first slots 106 may comprise filled slots. As shown in FIG. 2A, the first slots 106 may be filled with P-type polysilicon fill 226 and undoped semiconductor fill 228. The P-type polysilicon fill 226 may fill the horizontal end regions (e.g., in the Y-direction) of the first slots 106. Within those horizontal end regions, the P-type polysilicon fill 226 may horizontally extend substantially the entire span in the X-direction of the individual first slots 106. The P-type polysilicon fill 226 may vertically (e.g., in the Z-direction) extend substantially the entire span of the first slots 106. The P-type polysilicon fill 226 may be formed of and include a doped polysilicon material incorporating a P-type dopant (e.g., polysilicon doped with boron, aluminum, or gallium). Elevations of the P-type polysilicon fill 226 that coincide in the Z-direction with the bottom polysilicon material 210 may be horizontally bounded by a generally ovular portion of a separator oxide material 230. The undoped semiconductor fill 228 may fill a center region (e.g., in the Y-direction) of the first slots 106, the center region being bounded by the horizontal end regions of the first slots 106. Within the center region, the undoped semiconductor fill 228 may horizontally extend substantially the entire span in the X-direction of the individual first slots 106. The undoped semiconductor fill 228 may vertically (e.g., in the Z-direction) extend substantially the entire span of the first slots 106. The undoped semiconductor fill 228 may be formed of and include a semiconductor material, such as substantially undoped semiconductor material (e.g., undoped polysilicon). The undoped semiconductor fill 228 may be horizontally bounded by a first slot vertical liner 232, such that the first slot vertical liner 232 horizontally (e.g., in the X- and Y-directions) separates the undoped semiconductor fill 228 from the sidewalls 224 of the first slots 106 in the X-direction and from the P-type polysilicon fill 226 in the Y-direction. The first slot vertical liner 232 may be formed of and include a dielectric oxide material (e.g., silicon oxide).

Following formation of the lower deck 208 of the preliminary stack structure 102, lower individual portions of the first slots 106 (e.g., at the vertical extent, in the Z-direction, of the lower deck 208, the bottom dielectric material 212, and the bottom polysilicon material 210) may be formed by removing portions (e.g., via a patterned mask) of the materials of the lower deck 208, bottom dielectric material 212, and bottom polysilicon material 210 of the preliminary stack structure 102, thereby forming voids having respective horizontal profiles (e.g., when viewed from a top-down perspective) of the first slots 106. The lower boundaries of the individual first slots 106 may be defined by the base structure liner material 214.

Following formation of the lower portions of the first slots 106 within the preliminary stack structure 102, exposed portions of the bottom polysilicon material 210 within the first slots 106 may be exposed to at least one oxidizing agent to form a separator oxide material 230 at an elevation of the sidewall 224 of the individual first slots 106 that coincides with the bottom polysilicon material 210.

Following formation of the separator oxide material 230, the P-type polysilicon fill 226 may be formed within the first slots 106 (e.g., substantially filling the individual first slots 106 with the P-type polysilicon fill 226). The P-type polysilicon fill 226 may continuously span substantially the vertical extent (e.g., in the Z-direction) within substantially the entire horizontal profile (e.g., in the X- and Y-directions) of the lower portions of the first slots 106.

Following formation of the P-type polysilicon fill 226, the P-type polysilicon fill 226 may be partially removed from the horizontal central regions (e.g., in the Y-direction) of individual first slots 106. The P-type polysilicon fill 226 may be partially removed using conventional material removal (e.g., photolithography using the pattern of the third slot regions 110 depicted in FIG. 1, and reactive ion etching of P-type polysilicon selective to photoresist and materials of the lower deck 208) techniques to pattern voids in the individual portions of the P-type polysilicon fill 226. The removal of the portion of the P-type polysilicon fill 226 may result in a void (e.g., having a substantially rectangular horizontal cross-sectional shape) spanning substantially the vertical extent (e.g., in the Z-direction) of the individual first slots 106. The void formed from the partial removal of the P-type polysilicon fill 226 may horizontally (e.g., in the X-direction) extend substantially the entire span of the individual first slots 106. P-type polysilicon fill 226 may remain in horizontal end regions (e.g., in the Y-direction) of individual first slots 106.

Following the partial removal of the P-type polysilicon fill 226, the first slot vertical liner 232 may be formed on vertical surfaces of the P-type polysilicon fill 226 and on sidewalls 224 of the first slots 106 that were exposed by the partial removal of the P-type polysilicon fill 226. The first slot vertical liner 232 may substantially cover and continuously extend across the exposed surfaces of the preliminary stack structure 102 within the first slots 106.

Following formation of the first slot vertical liners 232, the undoped semiconductor fill 228 may be formed (e.g., deposited) within the individual first slots 106 in the voids where the P-type polysilicon fill 226 was partially removed. The undoped semiconductor fill 228 may substantially fill the void space within the horizontal central regions (e.g., in the Y-direction) of individual first slots 106. Following formation of the undoped semiconductor fill 228, portions of the P-type polysilicon fill 226, undoped semiconductor fill 228, and first slot vertical liner 232 overlying an uppermost surface (e.g., in the Z-direction) of the lower deck 208 of the preliminary stack structure 102 may be removed (e.g., through an abrasive planarization process, such as a CMP process). Removal of the P-type polysilicon fill 226, undoped semiconductor fill 228, and first slot vertical liner 232 may leave upper surfaces (e.g., in the Z-direction) of the P-type polysilicon fill 226, undoped semiconductor fill 228, and first slot vertical liner 232 substantially coplanar with upper surfaces of the lower deck 208 of the preliminary stack structure 102 (e.g., an upper surface of the sacrificial material 202 of an uppermost tier 206 of the preliminary stack structure 102).

The preliminary stack structure 102 may be formed to include one or more decks, with each deck comprising multiple tiers 206. As depicted in FIG. 2B, the preliminary stack structure 102 may include the lower deck 208 and an upper deck 234 vertically overlying (e.g., in the Z-direction) the lower deck 208. Following formation of the P-type polysilicon fill 226 and undoped semiconductor fill 228 within the first slots 106 of the lower deck 208 of the preliminary stack structure 102, the upper deck 234 of the preliminary stack structure 102 may be formed. The upper deck 234 may be formed over the lower deck 208 by forming a vertically alternating sequence of the sacrificial material 202 and the insulative material 204. Following formation of the upper deck 234, a top insulative material 236 may be formed over the upper deck 234, followed by forming a top sacrificial material 238 over the top insulative material 236. The top insulative material 236 may be formed of and include insulative material. The top insulative material 236 may be vertically thicker (e.g., in the Z-direction) than the insulative material 204 and/or the sacrificial material 202 of individual tiers 206 of the preliminary stack structure 102. Similarly, the top sacrificial material 238 may be vertically thicker (e.g., in the Z-direction) than the insulative material 204 and/or the sacrificial material 202 of individual tiers 206 of the preliminary stack structure 102.

The decks (e.g., lower deck 208, upper deck 234) of the preliminary stack structure 102 may individually include any desired number of tiers 206. By way of non-limiting example, the lower deck 208 and the upper deck 234 of the preliminary stack structure 102 may individually include ten (10) tiers 206. Alternatively, the lower deck 208 and the upper deck 234 of the preliminary stack structure 102 may individually include fewer than ten (10) tiers 206. As further non-limiting examples, the lower deck 208 and the upper deck 234 of the preliminary stack structure 102 may individually include greater than or equal to ten (10) of the tiers 206, such as greater than or equal to sixteen (16) of the tiers 206, greater than or equal to thirty-two (32) of the tiers 206, greater than or equal to sixty-four (64) of the tiers 206, or greater than or equal to one hundred and twenty-eight (128) of the tiers 206.

Still referring to FIG. 2B, following formation of the upper deck 234 of the preliminary stack structure 102, upper portions of the first slots 106 (e.g., at the vertical extent, in the Z-direction, of the upper deck 234) may be formed by removing portions (e.g., via a patterned mask) of the materials of the upper deck 234, top insulative material 236, and top sacrificial material 238, thereby forming voids having respective horizontal profiles of the first slots 106. The individual horizontal profiles of the upper portions of the first slots 106 may be substantially horizontally aligned (e.g., in the X- and Y-directions) with the individual horizontal profiles of the lower portions of the first slots 106. However, the upper portions of the first slots 106 may be partially horizontally (e.g., in the X- and/or Y-directions) offset (e.g., partially horizontally misaligned) with respect to the corresponding lower portions of the first slots 106, thereby resulting in an upper deck overhang 240. Additionally or alternatively, the sidewalls 224 partially defining the first slots 106 may exhibit a taper. If tapered, the sidewalls 224 may be positively sloped or may be negatively sloped. If tapered, the sidewalls 224 partially defining the first slots 106 may result in differently-sized horizontal profiles of portions of the first slots 106 within the lower deck 208 than additional portions of the first slots 106 within the upper deck 234. For example, at the interface between the lower deck 208 and the upper deck 234 within an individual first slot 106, the horizontal span in the X- and Y-directions between opposing sidewalls 224 partially defining the first slots 106 vary from the upper deck 234 to the lower deck 208. A downward-facing lower (e.g., in the Z-direction) edge of the upper deck 234 of the preliminary stack structure 102 may be exposed by the partial horizontal offset between the upper portions of the first slots 106 (e.g., at the upper deck 234) and the lower portions of the first slots 106 (e.g., at the lower deck 208). Alternatively, a horizontal offset between the upper portions of the first slots 106 and the lower portions of the first slots 106 may form a shoulder between the lower deck 208 and the upper deck 234. In such embodiments, an edge, facing upward in the Z-direction, of the lower deck 208 of the preliminary stack structure 102 is exposed by the partial horizontal offset between the upper deck 234 and the lower deck 208. In additional embodiments, the preliminary stack structure 102 exhibits substantially no horizontal offset, horizontal misalignment, and/or taper between the lower deck 208 and the upper deck 234.

Following formation of the upper portions of the first slots 106, the P-type polysilicon fill 226 may be formed within and over the upper portions of the first slots 106 (e.g., substantially filling the individual upper portions of the first slots 106 with the P-type polysilicon fill 226). The P-type polysilicon fill 226 may continuously span substantially the vertical extent (e.g., in the Z-direction) of the upper deck 234, the top insulative material 236, and the top sacrificial material 238 within substantially the entire horizontal profile (e.g., in the X- and Y-directions) of the first slots 106. Further, the P-type polysilicon fill 226 may be formed to substantially extend across and at least partially cover the exposed upper surfaces, in the Z-direction, of the top sacrificial material 238. The P-type polysilicon fill 226 may conform to a topography partially defined by the upper surface of the top sacrificial material 238.

Following formation of the P-type polysilicon fill 226 within the upper portions of the first slots 106, the P-type polysilicon fill 226 may be partially removed, forming individual voids within the first slots 106 and forming third slots within the third slot regions 110 (FIG. 1). The P-type polysilicon fill 226 may be removed from horizontal central regions of the upper portions of the first slots 106 that overlie, in the Z-direction, the undoped semiconductor fill 228 (FIG. 2A) in the lower deck 208 of the preliminary stack structure 102. The P-type polysilicon fill 226 may be partially removed by conventional material removal (e.g., photolithography, etching) techniques to pattern voids in the individual portions of the P-type polysilicon fill 226. The portion of the P-type polysilicon fill 226 removed may result in individual voids within horizontal areas of the first slots 106 (e.g., having a substantially rectangular horizontal cross-sectional shape horizontally aligned with the undoped semiconductor fill 228) spanning substantially the vertical extent (e.g., in the Z-direction) of the upper deck 234 of the preliminary stack structure 102, the top insulative material 236, and the top sacrificial material 238; and may further result in the third slots spanning substantially the vertical extent (e.g., in the Z-direction) of the top sacrificial material 238. The partial removal of the P-type polysilicon fill 226 may expose portions of the undoped semiconductor fill 228 within the first slots 106 in the lower deck 208 and may expose upper surfaces (e.g., in the Z-direction) of the top sacrificial material 238 horizontally disposed in the X-direction between neighboring first slots 106.

Following the partial removal of the P-type polysilicon fill 226, the undoped semiconductor fill 228 and the first slot vertical liner 232 may be substantially all removed (e.g., exhumed) from the lower portion of the individual first slots 106. The first slot vertical liner 232 and then the undoped semiconductor fill 228 may be removed in sequence (e.g., using two or more discrete processing acts), or the first slot vertical liner 232 and the undoped semiconductor fill 228 may be jointly removed (e.g., using a single processing act). Removal of the undoped semiconductor fill 228 and the first slot vertical liner 232 may expose portions of the sidewalls 224 (e.g., the tiers 206) of the first slots 106 and vertical portions of the P-type polysilicon fill 226 within the first slots 106.

Still referring to FIG. 2B, following removal of the undoped semiconductor fill 228 and the first slot vertical liner 232, a dielectric mask material 242a may be formed over exposed surfaces of the preliminary stack structure 102. The dielectric mask material 242a may substantially continuously extend across and cover the exposed surfaces of the preliminary stack structure 102 defining the first slots 106 (e.g., the sidewalls 224), the exposed surfaces of the preliminary stack structure 102 defining the third slots, and the exposed surfaces of the P-type polysilicon fill 226. The dielectric mask material 242a within the first slots 106 may define a horizontal perimeter of the horizontal central region of the individual first slots 106. The dielectric mask material 242a may conform to a topography of upper surfaces of the top sacrificial material 238 and the P-type polysilicon fill 226. The dielectric mask material 242a may be provided inside and outside of the first slots 106 and the third slots. The dielectric mask material 242a may be formed of and include at least one material having an etch selectivity relative to the semiconductive mask material 244, the second semiconductive mask material 246 (FIG. 2D), the trim material 248 (FIG. 2D), the first oxide mask material 250a (FIG. 2E), and the sacrificial material 202 and insulative material 204 of the tiers 206. The dielectric mask material 242a may be formed of and include dielectric oxide material, such as metal oxide dielectric material.

Following formation of the dielectric mask material 242a, a semiconductive mask material 244 may be formed over exposed surfaces of the preliminary stack structure 102. The semiconductive mask material 244 may substantially continuously extend across and cover the exposed surfaces (e.g., the sidewalls 224 (FIG. 2A)) defining the first slots 106. The semiconductive mask material 244 may conform to a topography of exposed surfaces of the dielectric mask material 242a. The semiconductive mask material 244 may be provided inside and outside of the first slots 106. The semiconductive mask material 244 may be formed to have a vertical extent (e.g., in the Z-direction) spanning the bottom polysilicon material 210, the bottom dielectric material 212, the tiers 206, and the top insulative material 236. The semiconductive mask material 244 may be formed of and include a semiconductor material, such as polysilicon. The semiconductive mask material 244 may be doped or may be undoped. By way of non-limiting example, the semiconductive mask material 244 may be formed of and include N-type doped polysilicon. The semiconductive mask material 244 may be formed to have a desired thickness, such as a thickness within a range of from approximately 5 nm to approximately 15 nm, such as approximately 10 nm.

Still referring to FIG. 2B, following formation of the semiconductive mask material 244, a sacrificial fill 252 may be formed (e.g., deposited) within remaining (e.g., unfilled) portions of the first slots 106 and the third slots. The sacrificial fill 252 may substantially continuously extend across and cover the exposed surfaces of the preliminary stack structure 102 defining the first slots 106 and the third slots. The sacrificial fill 252 may be formed over the semiconductive mask material 244, may substantially fill the horizontal central regions of the first slots 106, and may substantially fill the third slots, thereby forming the third filled slots 254. The sacrificial fill 252 may initially be non-conformally formed (e.g., non-conformally deposited) inside and outside of the first slots 106 and the third filled slots 254. The sacrificial fill 252 may be formed of and include at least one material having an etch selectivity relative to the P-type polysilicon fill 226, the dielectric mask material 242a, and the semiconductive mask material 244. In some embodiments, the sacrificial fill 252 is formed of and includes one of carbon material and silicon-germanium material.

Following formation of the sacrificial fill 252, upper portions of the sacrificial fill 252, the semiconductive mask material 244, the dielectric mask material 242a, and the P-type polysilicon fill 226 overlying upper boundaries of the top sacrificial material 238 may be removed (e.g., by way of CMP) to substantially planarize the uppermost boundaries of the sacrificial fill 252, the semiconductive mask material 244, the dielectric mask material 242a, and the P-type polysilicon fill 226 relative to one another. The material removal process may form a substantially planar upper horizontal surface defined by and including coplanar upper horizontal surfaces of the P-type polysilicon fill 226, the dielectric mask material 242a, the semiconductive mask material 244, and the sacrificial fill 252.

Referring to FIG. 2C, following formation of the sacrificial fill 252, the P-type polysilicon fill 226 (FIG. 2B) may be removed (e.g., exhumed). Substantially all of the P-type polysilicon fill 226 may be removed. Removal of the P-type polysilicon fill 226 may expose the sidewalls 224 of the microelectronic device structure 100 partially defining the first slots 106 and portions of the dielectric mask material 242a within the first slots 106.

Following removal of the P-type polysilicon fill 226, exposed portions of the dielectric mask material 242a may be removed. As depicted in FIG. 2C, portions of the dielectric mask material 242a spanning in the X-direction between opposing sidewalls 224 of the first slots 106 are removed. Removal of portions of the dielectric mask material 242a may expose portions of the semiconductive mask material 244 within the first slots 106.

Following partial removal of the dielectric mask material 242a, exposed portions of the semiconductive mask material 244 may be removed. As depicted in FIG. 2C, portions of the semiconductive mask material 244 spanning in the X-direction between opposing remaining portions of the dielectric mask material 242a within the first slots 106 are removed. Removal of portions of the semiconductive mask material 244 may expose portions of the sacrificial fill 252 within the first slots 106.

Following partial removal of the semiconductive mask material 244, exposed portions of the sacrificial fill 252 may be partially removed (e.g., recessed). As depicted in FIG. 2C, portions of the sacrificial fill 252 spanning in the X-direction between opposing remaining portions of the semiconductive mask material 244 within the first slots 106 are removed.

Referring to FIG. 2D, following the partial removal of the sacrificial fill 252 (FIG. 2C), additional dielectric material may be formed on and over the remaining sacrificial fill 252, the semiconductive mask material 244, the dielectric mask material 242a, and the sidewalls 224 within the first slots 106, to form a second dielectric mask material 242b including the dielectric mask material 242a (FIG. 2C). The dielectric mask material 242b may substantially cover and continuously extend across the exposed surfaces of the sacrificial fill 252, the semiconductive mask material 244, and the sidewalls 224 within the first slots 106. The dielectric mask material 242b may include one or more bridge portions 242c extending in the X-direction across the first slots 106 and adjacent to the sacrificial fill 252. The bridge portions 242c may comprise one or more portions of the dielectric mask material 242b formed on or over the sacrificial fill 252. The dielectric mask material 242b may be formed of and include substantially the same material as the dielectric mask material 242a.

Following formation of the dielectric mask material 242b, a second semiconductive mask material 246 may be formed on and over the dielectric mask material 242b within the first slots 106. The second semiconductive mask material 246 may substantially continuously extend across and cover the exposed surfaces of the dielectric mask material 242b within the first slots 106. The second semiconductive mask material 246 may be separated in the Y-direction from the semiconductive mask material 244 by the bridge portion 242c of the dielectric mask material 242b. The second semiconductive mask material 246 may be formed of and include a semiconductor material, such as polysilicon. The second semiconductive mask material 246 may be doped or may be undoped. By way of non-limiting example, the second semiconductive mask material 246 may be formed of and include N-type doped polysilicon.

Following formation of the second semiconductive mask material 246, a trim material 248 may be formed on and over the second semiconductive mask material 246 within the first slots 106. The trim material 248 may substantially continuously extend across and cover the exposed surfaces of the second semiconductive mask material 246 within the first slots 106. The trim material 248 may be formed of and include at least one material having different etch selectivity than the dielectric mask material 242b, the second semiconductive mask material 246, and some subsequently formed materials (e.g., the second sacrificial fill 256, the second oxide mask material 250b (FIG. 2G)). In some embodiments, the trim material 248 is formed of and includes a dielectric nitride material (e.g., silicon nitride). In additional embodiments, the trim material 248 is formed of and includes a dielectric nitride material and an additional material (e.g., a core material), having a different material composition than the dielectric nitride material, on or over the dielectric nitride material. As depicted in FIG. 2D, one individual portion of the trim material 248 may be formed within a horizontal end region (e.g., in the Y-direction) of the individual first slots 106 (e.g., two individual portions of the trim material 248 are formed per individual first slot 106).

Still referring to FIG. 2D, following formation of the trim material 248, a second sacrificial fill 256 may be formed on or over the trim material 248 within the first slots 106. The second sacrificial fill 256 may at least partially (e.g., substantially) fill unfilled portions of the first slots 106 having boundaries partially defined by inner surfaces of the trim material 248. In some embodiments, the second sacrificial fill 256 substantially fills remaining (e.g., unfilled) portions of the first slots 106 between horizontally opposing portions of the trim material 248 at each horizontal end region in the Y-direction of the individual first slots 106. The second sacrificial fill 256 may be formed of and include at least one material having an etch selectivity relative to the dielectric mask material 242b, the second semiconductive mask material 246, the trim material 248, and the second oxide mask material 250b (FIG. 2G). In some embodiments, the second sacrificial fill 256 is formed of and includes aluminum oxide-containing material.

Following formation of the second sacrificial fill 256, the sacrificial fill 252 (FIG. 2C) may be removed (e.g., exhumed). The sacrificial fill 252 may be removed at substantially the entire vertical extent (e.g., in the Z-direction) of the first slots 106. Removal of the sacrificial fill 252 may expose the semiconductive mask material 244 and portions (e.g., bridge portions 242c) of the dielectric mask material 242b within the first slots 106.

Referring to FIG. 2E through FIG. 21, a series of processing acts is shown and described that result in the formation of multiple memory cell positions 258a, 258b (FIG. 2H), horizontally separated from one another in the Y-direction, within the individual first slots 106. The formation of individual memory cell positions 258a, 258b may be accomplished by successive trim and etch processing acts. The widths and/or pitches in the Y-direction of the memory cell positions 258a, 258b may be determined, in part, by a respective horizontal extent, in the Y-direction, of the second semiconductive mask material 246 and/or trim material 248 removed (e.g., trimmed back) during respective trim and etch processing acts, as described in further detail below. The horizontal extent, in the Y-direction, of the second semiconductive mask material 246 and/or trim material 248 removed may be controlled, as desired, by choosing an etchant composition according to predetermined etching rates, by choosing the duration of the material removal process, and/or by choosing other parameters of the material removal process.

Referring to FIG. 2E, following removal of the sacrificial fill 252, the semiconductive mask material 244 (FIG. 2D) within the first slots 106 may be substantially transformed (e.g., converted, oxidized) into a first oxide mask material 250a. In some embodiments, the first oxide mask material 250a is formed of and includes a dielectric oxide material, such as silicon oxide (e.g., SiO₂). The first oxide mask material 250a may be formed by converting exposed portions of the semiconductive mask material 244 to oxide (e.g., by thermal or plasma oxidation). The first oxide mask material 250a may be formed to continuously span a horizontal width in the Y-direction between adjacent bridge portions 242c (FIG. 2D) of the dielectric mask material 242b within the first slots 106. Further, the first oxide mask material 250a may continuously span substantially an entire vertical extent (e.g., in the Z-direction) of the preliminary stack structure 102 within the first slots 106.

Following formation of the first oxide mask material 250a, the bridge portions 242c (FIG. 2D) of the dielectric mask material 242b may be at least partially (e.g., substantially) removed. Removal of the bridge portions 242c of the dielectric mask material 242b may expose portions of the second semiconductive mask material 246 within the first slots 106.

Following partial removal of the dielectric mask material 242b, a portion of the second semiconductive mask material 246 may be removed (e.g., via a tetramethylammonium hydroxide (“TMAH”) wet etch operation) to horizontally recede, in the Y-direction, the individual mask material edge 260 away from the horizontal center, in the Y-direction, of the respective first slot 106. Removing the portion of the second semiconductive mask material 246 may expose a portion of the trim material 248. By removing the portion of the second semiconductive mask material 246, a mask material edge 260 may be selectively horizontally located at memory cell positions 258a.

Further, the extent of horizontal removal of the second semiconductive mask material 246 may control the horizontal placement of the memory cell positions 258a. By removing a horizontal extent, in the Y-direction, of the second semiconductive mask material 246, the mask material edges 260 may be horizontally receded in the Y-direction to selected new horizontal positions to result in desired horizontal positions, in the Y-direction, of the memory cell positions 258a.

Referring to FIG. 2F, following locating the mask material edges 260 at the memory cell positions 258a in the first slots 106, portions of the trim material 248 may be removed (e.g., trimmed) to expose portions of the second semiconductive mask material 246. The removal of the trim material 248 may include exposing trim material edges 262 to at least one etchant (e.g., hot phosphoric acid etchant). By removing the portions of the trim material 248, the trim material edges 262 may be selectively horizontally located at respective horizontal distances, in the Y-direction from the memory cell positions 258a, that define a memory cell pitch 264. As such, the extent of horizontal removal of the trim material 248 may control the horizontal extent of the memory cell pitch 264.

Referring to FIG. 2G, following locating the trim material edges 262 in the first slots 106, an exposed portion of the second semiconductive mask material 246 (FIG. 2F) is substantially transformed (e.g., converted, oxidized) into a second oxide mask material 250b. In some embodiments, the second oxide mask material 250b is formed of and includes a dielectric oxide material, such as silicon oxide (e.g., SiO₂). The second oxide mask material 250b may be formed by converting exposed portions of the second semiconductive mask material 246 to oxide (e.g., by thermal oxidation or plasma oxidation). The combined distance of the second oxide mask material 250b and the gap between the first oxide mask material 250a and the second oxide mask material 250b may horizontally span the memory cell pitch 264 in the Y-direction.

Referring to FIG. 2H, following the formation of the second oxide mask material 250b, additional portions of the trim material 248 may be removed (e.g., trimmed) to expose additional portions of the second semiconductive mask material 246. The removal of the trim material 248 may include exposing the trim material edges 262 to at least one etchant. Removing the additional portions of the trim material 248 may selectively horizontally recede, in the Y-direction, the trim material edges 262 away from the horizontal center, in the Y-direction, of the respective first slot 106.

Following horizontally relocating the trim material edges 262 in the first slots 106, additional exposed portions of the second semiconductive mask material 246 within an individual first slot 106 may be removed to horizontally recede, in the Y-direction, the mask material edges 260 away from the horizontal center, in the Y-direction, of the first slot 106. Removing the additional portions of the second semiconductive mask material 246 may selectively horizontally relocate the mask material edges 260 at additional memory cell positions 258b. The extent of horizontal removal of the second semiconductive mask material 246 may control the horizontal placement in the Y-direction of the additional memory cell positions 258b.

Referring to FIG. 21, following locating the mask material edges 260 at the additional memory cell positions 258b in the first slots 106, the second sacrificial fill 256 (FIG. 2H) may be removed from the first slots 106. The second sacrificial fill 256 may be removed at substantially the entire vertical extent (e.g., in the Z-direction) of the first slots 106.

Following removal of the second sacrificial fill 256, the remaining portions of the trim material 248 (FIG. 2H) may be removed from the first slots 106 to expose remaining portions of the second semiconductive mask material 246. The trim material 248 may be removed at substantially the entire vertical extent (e.g., in the Z-direction) of the first slots 106.

Following removal of the trim material 248, the remaining portion of the second semiconductive mask material 246 (FIG. 2H) may be substantially transformed (e.g., converted, oxidized) into a third oxide mask material 250c. The third oxide mask material 250c may be formed by converting exposed portions of the second semiconductive mask material 246 to oxide (e.g., by thermal oxidation or plasma oxidation).

As shown in FIG. 21, memory cell positions 258a, 258b are defined by horizontal gaps, in the Y-direction, between adjacent portions of the first oxide mask material 250a, the second oxide mask material 250b, and the third oxide mask material 250c. Individual gaps at the memory cell position 258a, 258b may expose respective portions of the dielectric mask material 242b adjacent to the sidewalls 224 within the first slots 106 of the preliminary stack structure 102. At the processing stage depicted in FIG. 21, four memory cell positions 258a, 258b are defined in a lateral half (e.g., sectioned at a midline of the first slot 106 along the Y-axis) of the individual first slot 106. Thus, individual first slots 106 may comprise eight memory cell positions 258a, 258b.

Still referring to FIG. 21, following the formation of the third oxide mask material 250c, exposed portions of the dielectric mask material 242b (e.g., exposed by way of the gaps between the first oxide mask material 250a, the second oxide mask material 250b, and the third oxide mask material 250c at the memory cell positions 258a, 258b) may be removed (e.g., via an atomic layer etch operation) from the sidewalls 224 of the microelectronic device structure 100 partially defining the first slots 106. As depicted in FIG. 21, removal of the exposed portions of the dielectric mask material 242b may expose portions of the sidewalls 224.

Referring to FIG. 2J, following removal of the portions of the dielectric mask material 242b, portions of the sacrificial material 202 and of the insulative material 204 of the tiers 206 of the preliminary stack structure 102 may be removed to form preliminary voids 266a in the preliminary stack structure 102. Additionally, the first oxide mask material 250a, the second oxide mask material 250b, and the third oxide mask material 250c may be substantially removed. The removal of portions of the sacrificial material 202 and the insulative material 204, and the removal of the first oxide mask material 250a, the second oxide mask material 250b, and the third oxide mask material 250c may include exposing the microelectronic device structure 100 to at least one etchant (e.g., hot fluoric acid etchant). The formation of the individual preliminary voids 266a may be effectuated via the gaps in the dielectric mask material 242b at the memory cell positions 258a, 258b. Individual preliminary voids 266a may horizontally align in the Y-direction with respective memory cell positions 258a, 258b and may span substantially the vertical extent (e.g., in the Z-direction) of the preliminary stack structure 102.

As a result of the formation of the preliminary voids 266a in the preliminary stack structure 102, the remaining dielectric mask material 242b may define recesses 268 within the preliminary voids 266a, the recesses 268 being blocked from direct communication (e.g., line-of-sight communication) with the first slots 106 by the position of the dielectric mask material 242b.

Referring to FIG. 2K, following the formation of the preliminary voids 266a, a third semiconductive mask material 270 may be formed (e.g., deposited) over exposed surfaces of the microelectronic device structure 100. The third semiconductive mask material 270 may substantially continuously extend across and cover the exposed surfaces of the dielectric mask material 242b within the first slots 106 and the exposed surfaces of the sacrificial material 202 and insulative material 204 within the individual preliminary voids 266a in the preliminary stack structure 102. The third semiconductive mask material 270 may substantially fill the recesses 268 within the individual preliminary voids 266a in the preliminary stack structure 102. The third semiconductive mask material 270 may conform to a topography of surfaces of the dielectric mask material 242b, the sacrificial material 202, and the insulative material 204 within horizontal areas of the first slots 106. The third semiconductive mask material 270 may be formed of and include a semiconductor material, such as polysilicon. The third semiconductive mask material 270 may be doped or may be undoped. By way of non-limiting example, the third semiconductive mask material 270 may be formed of and include N-type doped polysilicon.

Following formation of the third semiconductive mask material 270, the third semiconductive mask material 270 may be partially removed (e.g., via an anisotropic wet etch operation). Some portions of the third semiconductive mask material 270 may remain in the recesses 268 in the preliminary voids 266a of the preliminary stack structure 102 as depicted in FIG. 2K. The remaining portions of the third semiconductive mask material 270 may comprise two laterally opposing (e.g., in the X-direction) portions separated by a mask material gap 272. The remaining portions of the third semiconductive mask material 270 within the recesses 268 may substantially cover corresponding portions of the sacrificial material 202 and the insulative material 204 of the preliminary stack structure 102. Other portions of the sacrificial material 202 and the insulative material 204 that are horizontally farther in the X-direction from the first slots 106 than the covered portions may remain exposed through the mask material gaps 272.

Referring to FIG. 2L, following removal of portions of the third semiconductive mask material 270, additional exposed portions of the sacrificial material 202 and of the insulative material 204 of the tiers 206 of the preliminary stack structure 102 may be removed. The removal of additional exposed portions of the sacrificial material 202 and the insulative material 204 may include exposing the microelectronic device structure 100 to at least one etchant (e.g., hot fluoric acid etchant). The removal of the additional exposed portions of the sacrificial material 202 and the insulative material 204 may be effectuated via the gaps in the dielectric mask material 242b at the memory cell positions 258a, 258b and via the mask material gaps 272. The removal of the additional exposed portions of the sacrificial material 202 and the insulative material 204 from the tiers 206 of the preliminary stack structure 102 may increase the size of the horizontal profiles of the individual preliminary voids 266a (FIG. 2K) in the preliminary stack structure 102 to convert preliminary voids 266a to voids 266b. During removal of the additional exposed portions of the sacrificial material 202 and the insulative material 204 of the tiers 206 of the preliminary stack structure 102, the third semiconductive mask material 270 (FIG. 2K) remaining within the voids 266b may impede the sacrificial material 202 and the insulative material 204 from being etched in the Y-direction while permitting the sacrificial material 202 and the insulative material 204 to be etched in X-direction. As a result, the voids 266b may respectively have a first horizontal extent (e.g., first width) in the X-direction, grown by the additional removal (e.g., wet etching) process, while a second horizontal extent (e.g., second width) in the Y-direction may remain substantially unchanged. An aspect ratio of an individual void 266b may be greater than about 0.5.

Following the removal of the additional exposed portions of the sacrificial material 202 and the insulative material 204, the third semiconductive mask material 270 may be substantially removed from the preliminary stack structure 102. Following the removal of the third semiconductive mask material 270, the dielectric mask material 242b may be substantially removed (e.g., via an atomic layer etch operation) from the preliminary stack structure 102. Alternatively, the dielectric mask material 242b may be removed along with removal of the third semiconductive mask material 270 (e.g., using a single processing act). As a result of the removal of the third semiconductive mask material 270 and the dielectric mask material 242b, the sacrificial material 202 and the insulative material 204 of the sidewalls 224 of the preliminary stack structure 102 may be substantially exposed by the first slots 106.

Following removal of the dielectric mask material 242b, a barrier oxide material 274 may be formed on or over exposed surfaces in the first slots 106 of the preliminary stack structure 102. The barrier oxide material 274 may continuously extend on or over exposed surfaces within horizontal areas of the first slots 106. The barrier oxide material 274 may substantially continuously extend across and cover the surfaces (e.g., the sidewalls 224) of the microelectronic device structure 100 exposed by and/or within the first slots 106. The barrier oxide material 274 may conform to a topography of the sidewalls 224 and exposed surfaces (e.g., vertically extending surfaces) of the voids 266b. The barrier oxide material 274 may be formed to continuously span substantially an entire combined vertical extent (e.g., in the Z-direction) of the sidewalls 224. The barrier oxide material 274 may be formed of and include dielectric oxide material (e.g., silicon oxide).

Following formation of the barrier oxide material 274, a storage nitride material 276 may be formed on or over exposed surfaces in the first slots 106 of the preliminary stack structure 102. The storage nitride material 276 may continuously extend on or over the barrier oxide material 274 within the horizontal areas of the first slots 106. The storage nitride material 276 may conform to a topography of exposed surfaces (e.g., vertically extending surfaces) of the barrier oxide material 274 inside and outside of the voids 266b. The storage nitride material 276 may be formed to continuously span substantially an entire vertical extent (e.g., in the Z-direction) of the barrier oxide material 274 within the first slots 106. The storage nitride material 276 may be formed of and include dielectric nitride material (e.g., silicon nitride).

Following formation of the storage nitride material 276, a tunnel oxide material 278 may be formed on or over exposed surfaces in the first slots 106 of the preliminary stack structure 102. The tunnel oxide material 278 may continuously extend on or over the storage nitride material 276 within the horizontal areas of the first slots 106. The tunnel oxide material 278 may conform to a topography of the exposed surfaces (e.g., vertically extending surfaces) of the storage nitride material 276 inside and outside of the voids 266b. The tunnel oxide material 278 may be formed to continuously span substantially an entire vertical extent (e.g., in the Z-direction) of the storage nitride material 276 within the first slots 106. The tunnel oxide material 278 may be formed of and include a dielectric oxide material (e.g., silicon oxide).

Following formation of the tunnel oxide material 278, a semiconductor material 280 may be formed on or over exposed surfaces within the horizontal areas of the first slots 106. The semiconductor material 280 may continuously extend on or over the tunnel oxide material 278 in the first slots 106. The semiconductor material 280 may conform to a topography of the exposed surfaces (e.g., vertically extending surfaces) of the tunnel oxide material 278 inside and outside of the voids 266b. The semiconductor material 280 may be formed to continuously span substantially an entire vertical extent (e.g., in the Z-direction) of the tunnel oxide material 278 within the first slots 106. The semiconductor material 280 may be doped or may be substantially undoped. In some embodiments, the semiconductor material 280 is formed of and includes doped polysilicon, such as N-type polysilicon (e.g., polysilicon doped with one or more N-type conductivity enhancing species, such as one or more of arsenic, phosphorous, and antimony).

The barrier oxide material 274, the storage nitride material 276, the tunnel oxide material 278, and the semiconductor material 280 may collectively be referred to as the memory cell material 282. The memory cell material 282 adjacent to the tiers 206 of the preliminary stack structure 102 and within the voids 266b may form preliminary vertical memory string structures 284a.

Following formation of the memory cell material 282, a core oxide material 286 may be formed on or over exposed surfaces within the horizontal areas of the first slots 106. The core oxide material 286 may continuously extend on or over the semiconductor material 280 in the first slots 106. The core oxide material 286 may conform to a topography of the exposed surfaces (e.g., vertically extending surfaces) of the semiconductor material 280 inside and outside of the voids 266b. The core oxide material 286 may be formed to continuously span substantially an entire vertical extent (e.g., in the Z-direction) of the semiconductor material 280 within the first slots 106. The core oxide material 286 may be formed of and include a dielectric material (e.g., dielectric oxide material, such as silicon oxide).

Referring to FIG. 2M, following formation of the core oxide material 286, exposed portions of the core oxide material 286 may be removed (e.g., the core oxide material 286 may be recessed) from the first slots 106. The core oxide material 286 may be removed to such a horizontal extent, in the X-direction, that portions of the semiconductor material 280 not in the voids 266b are exposed. Other portions of the core oxide material 286 in the voids may substantially remain in place after removal of the portions of the core oxide material 286.

Following removal of portions of the core oxide material 286, exposed portions of the semiconductor material 280 may be removed (e.g., the semiconductor material 280 may be recessed) from the first slots 106. In removing the exposed portions of the semiconductor material 280, other portions of the semiconductor material 280 within the voids 266b may substantially remain. Individual remaining portions of the semiconductor material 280 within the voids 266b may be discontinuous with respect to other portions of the semiconductor material 280 within other voids 266b. Removing exposed portions of the semiconductor material 280 may convert the preliminary vertical memory string structures 284a to vertical memory string structures 284b. As such, the vertical memory string structures 284b may be positioned at and around the outer horizontal boundaries of the first slots 106 at respective memory cell positions 258a, 258b. Eight vertical memory string structures 284b may be positioned at and around the outer horizontal boundaries of individual first slots 106.

In the individual vertical memory string structures 284b, the semiconductor material 280 may have a horizontal profile forming a U-shape, having two opposing side portions extending in the X-direction and a central connecting portion extending in the Y-direction. The two side portions of the horizontal profile of the semiconductor material 280 may be separated in the Y-direction by the core oxide material 286. The central connecting portion of the horizontal profile of the semiconductor material 280 may be directly adjacent to the tunnel oxide material 278 in the X-direction, while the side portions of the horizontal profile of the semiconductor material 280 may be directly adjacent to the tunnel oxide material 278 in the Y-direction. The semiconductor material 280 may be partially horizontally encompassed by or within a multi-material stack (e.g., the barrier oxide material 274, the storage nitride material 276, and the tunnel oxide material 278). In one embodiment, the tunnel oxide material 278 is directly adjacent to the semiconductor material 280 on two sides (e.g., two opposing sides) in the Y-direction and one side (e.g., only a single side) in the X-direction. In one embodiment, the semiconductor material 280 has three outer horizontal boundaries surrounded by the sacrificial material 202 of the tiers 206 of the preliminary stack structure 102.

The barrier oxide material 274, the storage nitride material 276, and the tunnel oxide material 278 may horizontally cover from about 70 percent to about 80 percent of an outer horizontal perimeter of the semiconductor material 280. Individual vertical memory string structures 284b may vertically span substantially the entire vertical extent (e.g., in the Z-direction) of the preliminary stack structure 102.

The tunnel oxide material 278 within an individual memory cell position 258a, 258b may have a horizontal profile forming a U-shape, having two opposing side portions extending in the X-direction and a central connecting portion extending in the Y-direction. The two side portions of the horizontal profile of the tunnel oxide material 278 may be separated in the Y-direction by the semiconductor material 280 and the core oxide material 286. The tunnel oxide material 278 at an individual memory cell position 258a, 258b may be partially horizontally encompassed by or within the barrier oxide material 274 and the storage nitride material 276.

The storage nitride material 276 within an individual memory cell position 258a, 258b may have a horizontal profile forming a U-shape, having two opposing side portions extending in the X-direction and a central connecting portion extending in the Y-direction. The two side portions of the horizontal profile of the storage nitride material 276 may be separated in the Y-direction by the tunnel oxide material 278, the semiconductor material 280, and the core oxide material 286. The storage nitride material 276 at an individual memory cell position 258a, 258b may be partially horizontally encompassed by or within the barrier oxide material 274.

The barrier oxide material 274 within an individual memory cell position 258a, 258b may have a horizontal profile forming a U-shape, having two opposing side portions extending in the X-direction and a central connecting portion extending in the Y-direction. The two side portions of the horizontal profile of the barrier oxide material 274 may be separated in the Y-direction by the storage nitride material 276, the tunnel oxide material 278, the semiconductor material 280, and the core oxide material 286. The barrier oxide material 274 at an individual memory cell position 258a, 258b may be partially horizontally encompassed by or within portions of the sacrificial material 202 and the insulative material 204 of the preliminary stack structure 102.

Referring to FIG. 2N, following formation of the vertical memory string structures 284b, a memory cell fill 288 may be formed within the first slots 106 (FIG. 2M), thereby forming first filled slots 290. The memory cell fill 288 may substantially fill portions of the first slots 106 remaining unfilled by the memory cell material 282 and the core oxide material 286. The memory cell fill 288 may be formed of and include a dielectric material (e.g., dielectric oxide material, such as silicon oxide).

At least one second slot (e.g., trench, opening, slit) may be formed within the second slot regions 108 (FIG. 1) and may vertically extend completely through the preliminary stack structure 102 (FIG. 2M). The second slot may be formed by removing portions of the preliminary stack structure 102 (including the tiers 206 (FIG. 2M) of insulative material 204 and sacrificial material 202 thereof). Additionally, the second slot may further vertically extend (e.g., in the Z-direction) through at least part of the bottom dielectric material 212, bottom polysilicon material 210, base structure liner material 214, upper base structure material 216, and middle base structure material 218. In some embodiments, the second slot vertically extends downward (e.g., in the Z-direction) through the lower base structure material 220.

Following the formation of the second slots, the bottom polysilicon material 210 (FIG. 2A), and portions of the separator oxide material 230 (FIG. 2A), the barrier oxide material 274 (FIG. 2M), the storage nitride material 276 (FIG. 2M), and the tunnel oxide material 278 (FIG. 2M) at a vertical position (e.g., in the Z-direction) of the bottom polysilicon material 210 (FIG. 2A), may be removed (e.g., wet etched) through the second slots and replaced with doped polysilicon material 210′. The doped polysilicon material 210′ may be formed of and include relatively heavily doped polysilicon (e.g., N+doped polysilicon), and may be employed as a source structure of the microelectronic device structure 100. The doped polysilicon material 210′ may contact the semiconductor material 280 at or proximate a boundary between the doped polysilicon material 210′ and the bottom dielectric material 212. Portions of the base structure liner material 214 may also be removed during the removal of the bottom polysilicon material 210 (FIG. 2A) and the portions of the separator oxide material 230 (FIG. 2A), the barrier oxide material 274 (FIG. 2M), the storage nitride material 276 (FIG. 2M), and the tunnel oxide material 278 (FIG. 2M). After the formation of the doped polysilicon material 210′ portions of the doped polysilicon material 210′ within the second slots may be removed (e.g., isotopically recessed), and the microelectronic device structure 100 may be subjected to replacement gate processing, as described in further detail below.

Following formation of the doped polysilicon material 210′, replacement gate processing may be effectuated to convert the preliminary stack structure 102 (FIG. 2M) into a stack structure 292. The replacement gate processing may at least partially (e.g., substantially) replace the sacrificial material 202 (FIG. 2M) of the tiers 206 (FIG. 2M) of the preliminary stack structure 102 (FIG. 2M) with conductive material 294. As shown in FIG. 2N, the stack structure 292 may include a vertically alternating (e.g., in the Z-direction) sequence of the insulative material 204 and the conductive material 294 arranged in tiers 206′.

The conductive material 294 of the tiers 206′ of the stack structure 292 may be formed of and include one or more of at least one metal, at least one alloy, at least one conductive metal-containing material (e.g., at last one conductive metal nitride, at least one conductive metal silicide, at least one conductive metal carbide, at least one conductive metal oxide), and at least one conductively doped semiconductor material (e.g., conductively doped polysilicon). In some embodiments, the conductive material 294 is formed of and includes W. Optionally, at least one liner material (e.g., at least one insulative liner material, at least one conductive liner materials) may be formed around the conductive material 294. The liner material may, for example, be formed of and include one or more a metal (e.g., titanium, tantalum), an alloy, a metal nitride (e.g., tungsten nitride, titanium nitride, tantalum nitride), and a metal oxide (e.g., aluminum oxide). In some embodiments, the liner material comprises at least one conductive material employed as a seed material for the formation of the conductive material 294. In some embodiments, the liner material comprises titanium nitride (TiNₓ, such as TiN). In further embodiments, the liner material further includes aluminum oxide (AlOₓ, such as Al₂O₃). As a non-limiting example, for each of the tiers 206′ of the stack structure 292, AlOₓ (e.g., Al₂O₃) may be formed directly adjacent the insulative material 204, TiNₓ (e.g., TiN) may be formed directly adjacent the AlOₓ, and W may be formed directly adjacent the TiNₓ. For clarity and case of understanding the description, the liner material is not illustrated in FIG. 2N, but it will be understood that the liner material may be disposed around the conductive material 294.

Still referring to FIG. 2N, the replacement gate processing employed to form the stack structure 292 may include treating the microelectronic device structure 100 with at least one wet etchant formulated to selectively remove (e.g., exhume) portions of the sacrificial material 202 (FIG. 2M) of the tiers 206 by way of the second slots. The wet etchant may be selected to remove the portions of the sacrificial material 202 without substantially removing portions of the insulative material 204 of the tiers 206 of the preliminary stack structure 102 (FIG. 2M), and without substantially removing portions of the base structure 104, the core oxide material 286, the memory cell material 282, and the memory cell fill 288. In some embodiments wherein the sacrificial material 202 comprises a dielectric nitride material (e.g., SiN_{y}, such as Si₃N₄) and the insulative material 204 comprises a dielectric oxide material (e.g., SiOₓ, such as SiO₂), the sacrificial material 202 of the tiers 206 of the preliminary stack structure 102 may be selectively removed using a wet etchant comprising H₃PO₄. Following the selective removal of the portions of the sacrificial material 202, the resulting recesses may be filled with the conductive material 294 by way of the second slots to form the stack structure 292 (including the tiers 206′ thereof). Following the formation of the stack structure 292, the second slots may be filled with insulative material (e.g., dielectric oxide material, such as silicon oxide), thereby forming second filled slots 296.

The stack structure 292 may include memory cells 298 located at intersections of the memory cell material 282 and conductive material 294 of the tiers 206′. Multiple vertical memory cells 298 in horizontal alignment (e.g., in the X- and Y-directions) make up an individual vertical memory string structure 284b. Individual vertical memory string structures 284b may vertically span substantially the entire vertical extent (e.g., in the Z-direction) of the stack structure 292. The memory cells 298 may individually comprise transistors. Some of the conductive material 294 may be employed as individual gate electrodes for corresponding memory cells 298 (e.g., transistors). The conductive material 294 may be adjacent to (e.g., in direct contact with) portions of the barrier oxide material 274 (FIG. 2M) of the memory cell material 282. The barrier oxide material 274 may be partially horizontally encompassed by or within portions of the conductive material 294 at elevations (e.g., in the Z-direction) of individual memory cells 298. As such, the memory cells 298 may individually comprise pseudo “gate-all-around” (GAA) transistors. Some of the conductive material 294 of the tiers 206′ may be employed as access line structures (e.g., word line structures) for the vertical memory string structures 284b. One or more of the lowermost tiers 206′ (e.g., in the Z-direction) of the stack structure 292 (e.g., select gate source (SGS) structure(s)), and one or more of the uppermost tiers 206′ (e.g., in the Z-direction) may be employed as second select gate structures (e.g., select gate drain (SGD) structure(s)).

The stack structure 292 of the microelectronic device structure 100 may be divided (e.g., segmented, partitioned) into blocks separated from one another (e.g., in the Y-direction) by filled trench structures (e.g., second filled slots 296). The second filled slots 296 may individually vertically extend (e.g., in the Z-direction) completely through the stack structure 292. At least some of the blocks of the stack structure 292 may horizontally extend substantially in parallel in the X-direction. Individual blocks of the stack structure 292 may exhibit substantially the same geometric configuration (e.g., substantially the same dimensions and substantially the same shape) as each other of the blocks, or one or more of the blocks may exhibit a different geometric configuration (e.g., one or more different dimensions and/or a different shape) than one or more other of the blocks. In addition, each pair of horizontally neighboring blocks of the stack structure 292 may be horizontally separated from one another by substantially the same distance (e.g., corresponding to a width in the Y-direction of individual second filled slots 296) as other pairs of horizontally neighboring blocks of the stack structure 292, or at least one pair of horizontally neighboring blocks of the stack structure 292 may be horizontally separated from one another by a different distance than that separating at least one other pair of horizontally neighboring blocks of the stack structure 292. In some embodiments, the blocks of the stack structure 292 are substantially uniformly (e.g., substantially non-variably, substantially equally, substantially consistently) sized, shaped, and spaced relative to one another. The individual blocks of the stack structure 292 may be further subdivided into sub-blocks, an individual sub-block being defined by the horizontal profile of a corresponding first filled slot 290. Thus, a sub-block may include the vertical memory string structures 284b on two (2) opposing (e.g., in the X-direction) sidewalls 224 of the stack structure 292.

Thus, in accordance with embodiments of the disclosure, a method of forming a microelectronic device includes forming a preliminary stack structure over a base structure. The preliminary stack structure includes tiers, each of the tiers comprising a sacrificial material and an insulative material vertically neighboring the sacrificial material. A first slot is formed to vertically extend through the preliminary stack structure. The first slot is partially defined by sidewalls of the preliminary stack structure horizontally extending in a first direction. A dielectric mask material is formed over exposed surfaces of the sidewalls of the preliminary stack structure partially defining the first slot. Gaps are formed in the dielectric mask material. The gaps expose surfaces of the sidewalls of the preliminary stack structure. Voids are formed in the sacrificial material and the insulative material of the preliminary stack structure via the gaps in the dielectric mask material. Memory cell material is formed within the voids. A portion of the memory cell material is removed to form vertical memory string structures vertically extending through the preliminary stack structure.

In accordance with other embodiments of the disclosure, a microelectronic device includes a stack structure comprising tiers. Each tier includes conductive material vertically neighboring insulative material. The stack structure is divided into blocks that are separated from one another in a first direction and that horizontally extend in parallel in a second direction. The second direction is substantially orthogonal to the first direction. At least one of the blocks includes first filled slots and vertical memory string structures. The vertical memory string structures are positioned at and around outer horizontal boundaries of the first filled slots. The first filled slots vertically extend completely through the tiers of the stack structure. The first filled slots are individually defined by two sidewalls of the stack structure that horizontally extend in the first direction. The vertical memory string structures are positioned at and around outer horizontal boundaries of the first filled slots. The vertical memory string structures include memory cell material that vertically extends completely through the tiers of the stack structure. The memory cell material includes semiconductor material and a multi-material stack. The multi-material stack substantially continuously extends across and surrounds multiple outer horizontal boundaries of the semiconductor material. The multi-material stack comprises barrier oxide material, storage nitride material, and tunnel oxide material.

In accordance with yet other embodiments of the disclosure, a memory device comprises a stack structure and dielectric-filled trenches vertically extending completely through the stack structure. The stack structure includes blocks that are separated from one another in a first direction and that horizontally extend in parallel in a second direction, orthogonal to the first direction. The stack structure includes tiers, each tier comprising conductive material and insulative material vertically neighboring the conductive material. The blocks individually include first filled slots vertically extending through the tiers. The first filled slots have memory string structures vertically extending through the tiers. The first filled slots include semiconductor material, dielectric oxide material, dielectric nitride material, and additional dielectric oxide. The semiconductor material is surrounded by the conductive material of the tiers of the stack structure. The dielectric oxide material is horizontally interposed between each of the three outer horizontal boundaries of semiconductive material and the conductive material of the tiers of the stack structure. The dielectric nitride material is horizontally interposed between the dielectric oxide material and the conductive material of the tiers of the stack structure. The additional dielectric oxide material is horizontally interposed between the dielectric nitride material and the conductive material of the tiers of the stack structure. The dielectric-filled trenches horizontally alternate with the blocks in the first direction.

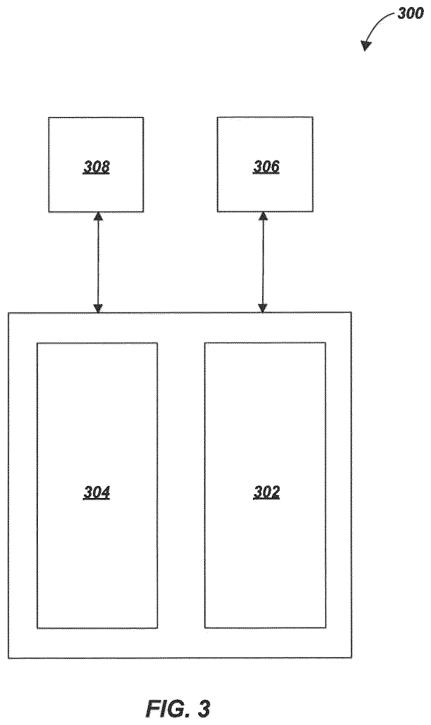

Microelectronic devices structures (e.g., the microelectronic device structure 100 previously described with reference to one or more of FIG. 1 and FIGS. 2A through 2N) in accordance with embodiments of the disclosure may be used in electronic systems. For example, FIG. 3 is a block diagram of an illustrative electronic system 300 according to embodiments of this disclosure. The electronic system 300 may comprise, for example, a computer or computer hardware component, a server or other networking hardware component, a cellular telephone, a digital camera, a personal digital assistant (PDA), portable media (e.g., music) player, a Wi-Fi or cellular-enabled tablet such as, for example, an iPad® tablet, a SURFACE® tablet, an electronic book, a navigation device.

The electronic system 300 includes at least one memory device 302. The memory device 302 may comprise, for example, the microelectronic device structure 100. The electronic system 300 may further include at least one electronic signal processor device 304 (often referred to as a “microprocessor”). The electronic signal processor device 304 may, optionally, include a microelectronic device structure 100. While the memory device 302 and the electronic signal processor device 304 are depicted as two separate devices in FIG. 3, in additional embodiments, a single (e.g., only one) memory/processor device having the functionalities of the memory device 302 and the electronic signal processor device 304 may be included in the electronic system 300. In such embodiments, the memory/processor device may include the microelectronic device structure 100. The electronic system 300 may further include one or more input devices 306 for inputting information into the electronic system 300 by a user, such as, for example, a mouse or other pointing device, a keyboard, a touchpad, a button, or a control panel. The electronic system 300 may further include one or more output devices 308 for outputting information (e.g., visual or audio output) to a user such as, for example, a monitor, a display, a printer, an audio output jack, a speaker, etc. In some embodiments, the input device 306 and the output device 308 comprise a single touchscreen device that can be used both to input information to the electronic system 300 and to output visual information to a user. The input device 306 and the output device 308 may communicate electrically with one or more of the memory device 302 and the electronic signal processor device 304.

The structures, devices, and methods of the disclosure advantageously facilitate one or more of improved microelectronic device performance, reduced costs (e.g., manufacturing costs, material costs), increased miniaturization of components, and greater packaging density as compared to conventional structures, conventional devices, and conventional methods. The structures, devices, and methods of the disclosure may also improve scalability, efficiency, and simplicity as compared to conventional structures, conventional devices, and conventional methods.

While the disclosure is susceptible to various modifications and alternative forms, specific embodiments have been shown by way of example in the drawings and have been described in detail herein. However, the disclosure is not limited to the particular forms disclosed. Rather, the disclosure is to cover all modifications, equivalents, and alternatives falling within the scope of the following appended claims and their legal equivalents. For example, elements and features disclosed in relation to one embodiment of the disclosure may be combined with elements and features disclosed in relation to other embodiments of the disclosure.

What is claimed is:

1. A method of forming a microelectronic device, comprising:
forming a preliminary stack structure over a base structure, the preliminary stack structure comprising tiers, each of the tiers comprising a sacrificial material and an insulative material vertically neighboring the sacrificial material;
forming a first slot vertically extending through the preliminary stack structure, the first slot partially defined by sidewalls of the preliminary stack structure horizontally extending in a first direction;
forming a dielectric mask material over exposed surfaces of the sidewalls of the preliminary stack structure partially defining the first slot;
forming gaps in the dielectric mask material, the gaps exposing surfaces of the sidewalls of the preliminary stack structure;
forming voids in the sacrificial material and the insulative material of the preliminary stack structure via the gaps in the dielectric mask material;
forming memory cell material within the voids; and
removing a portion of the memory cell material to form vertical memory string structures vertically extending through the preliminary stack structure.

2. The method of claim 1, wherein forming the gaps in the dielectric mask material comprises:
forming a first oxide mask material, a second oxide mask material, and a third oxide mask material over the dielectric mask material, wherein:
the first oxide mask material and the second oxide mask material are separated in the first direction by a first oxide material gap; and
the second oxide mask material and the third oxide mask material are separated in the first direction by a second oxide material gap; and
partially removing the dielectric mask material via the first oxide material gap and the second oxide material gap to form the gaps in the dielectric mask material.

3. The method of claim 2, further comprising:
forming a first polysilicon mask material over the dielectric mask material;
forming a second polysilicon mask material over the dielectric mask material, the second polysilicon mask material horizontally separated from the first polysilicon mask material in the first direction;
forming a trim material over the second polysilicon mask material; and
converting the first polysilicon mask material to the first oxide mask material.

4. The method of claim 3, further comprising:
removing a first portion of the second polysilicon mask material;
removing a first portion of the trim material to expose a second portion of the second polysilicon mask material;
converting the second portion of the second polysilicon mask material to the second oxide mask material to form the first oxide material gap;
removing a second portion of the trim material to expose a third portion of the second polysilicon mask material;
removing the third portion of the second polysilicon mask material;
removing a third portion of the trim material to expose a fourth portion of the second polysilicon mask material; and
converting the fourth portion of the second polysilicon mask material to the third oxide mask material to form the second oxide material gap.

5. The method of claim 4, further comprising:
forming a first portion of the dielectric mask material in a horizontal central region of the first slot, the first portion of the dielectric mask material defining a horizontal perimeter of the horizontal central region of the first slot;
forming the first polysilicon mask material over the dielectric mask material in the horizontal central region of the first slot;
forming a first sacrificial fill in the horizontal central region of the first slot;
forming a second portion of the dielectric mask material over the sidewalls of the first slot in a horizontal end region thereof, the second portion of the dielectric mask material comprising a bridge portion of the dielectric mask material that spans in a second direction, substantially orthogonal to the first direction, across the first slot; and
forming the second polysilicon mask material over the dielectric mask material in the horizontal end region of the first slot, the second polysilicon mask material horizontally separated from the first polysilicon mask material in the first direction by the bridge portion of the dielectric mask material.

6. The method of claim 1, further comprising replacing the sacrificial material of the tiers of the preliminary stack structure with conductive material after forming the vertical memory string structures.

7. The method of claim 1, wherein forming the memory cell material comprises:
forming a barrier oxide material over the sidewalls of the preliminary stack structure partially defining the first slot;
forming a storage nitride material over the barrier oxide material;
forming a tunnel oxide material over the storage nitride material; and
forming a semiconductor material over the tunnel oxide material.

8. The method of claim 7, wherein removing the portion of the memory cell material comprises removing a portion of the semiconductor material.

9. The method of claim 7, further comprising partially horizontally encompassing the semiconductor material within the barrier oxide material, the storage nitride material, and the tunnel oxide material.

10. The method of claim 9, further comprising forming the semiconductor material to be horizontally adjacent to the tunnel oxide material on two opposing sides of the semiconductor material in the first direction and a single side of the semiconductor material in a second direction, substantially orthogonal to the first direction.

11. The method of claim 1, wherein forming voids in the sacrificial material and the insulative material of the preliminary stack structure via the gaps in the dielectric mask material comprises:
forming preliminary voids in the sacrificial material and the insulative material of the preliminary stack structure via the gaps in the dielectric mask material, the preliminary voids individually having recesses blocked from direct communication with the first slot by the dielectric mask material;
forming a third polysilicon mask material in the recesses, the third polysilicon mask material having a horizontal gap therein substantially aligned with the gaps in the dielectric mask material; and
enlarging the preliminary voids via the gaps in the dielectric mask material and the gaps in the third polysilicon mask material to convert the preliminary voids to the voids in the sacrificial material and the insulative material.

12. A microelectronic device, comprising:
a stack structure comprising tiers each including conductive material vertically neighboring insulative material, the stack structure divided into blocks separated from one another in a first direction and horizontally extending in parallel in a second direction substantially orthogonal to the first direction, at least one of the blocks comprising:
first filled slots vertically extending completely through the tiers of the stack structure and individually defined by two sidewalls of the stack structure horizontally extending in the first direction; and
vertical memory string structures positioned at and around outer horizontal boundaries of the first filled slots, the vertical memory string structures comprising: memory cell material vertically extending completely through the tiers of the stack structure, the memory cell material comprising:
semiconductor material; and
a multi-material stack substantially continuously extending across and surrounding multiple outer horizontal boundaries of the semiconductor material, the multi-material stack comprising barrier oxide material, storage nitride material, and tunnel oxide material.

13. The microelectronic device of claim 12, wherein the tunnel oxide material is horizontally adjacent to the semiconductor material on two sides in the first direction and at least on one side in the second direction.

14. The microelectronic device of claim 12, wherein the barrier oxide material, the storage nitride material, and the tunnel oxide material horizontally cover from about 70 percent to about 80 percent of an outer horizontal perimeter of the semiconductor material.

15. The microelectronic device of claim 12, wherein the semiconductor material has a U-shaped horizontal profile.

16. The microelectronic device of claim 15, further comprising a core oxide material horizontally separating two opposing portions of the semiconductor material in the first direction.

17. The microelectronic device of claim 12, wherein eight of the vertical memory string structures are positioned within a horizontal area of one of the first filled slots.

18. A memory device, comprising:
a stack structure comprising blocks separated from one another in a first direction and horizontally extending in parallel in a second direction orthogonal to the first direction, the stack structure including tiers, each comprising conductive material and insulative material vertically neighboring the conductive material, the blocks individually comprising:
first filled slots vertically extending through the tiers and comprising memory string structures vertically extending through the tiers and individually comprising:
semiconductor material surrounded by the conductive material of the tiers of the stack structure;
dielectric oxide material horizontally interposed between each of the three outer horizontal boundaries of semiconductive material and the conductive material of the tiers of the stack structure;
dielectric nitride material horizontally interposed between the dielectric oxide material and the conductive material of the tiers of the stack structure; and
additional dielectric oxide material horizontally interposed between the dielectric nitride material and the conductive material of the tiers of the stack structure; and
dielectric-filled trenches vertically extending completely through the stack structure and horizontally alternating with the blocks in the first direction.

19. The memory device of claim 18, wherein the semiconductor material of each of the memory string structures exhibits a U-shaped horizontal profile.

20. The memory device of claim 19, wherein the first filled slots individually further comprise a core oxide material partially horizontally encompassed by inner horizontal boundaries of the semiconductor material.
